(19) United States
(12) Patent Application Publication
(10) Pub. No.: US 2026/0262486 A1
(43) Pub. Date: Sep. 3, 2026

(54) COMPLEMENTARY FIELD-EFFECT TRANSISTOR (CFET) ARCHITECTURE

(71) Applicant: QUALCOMM Incorporated, San Diego, CA (US)

(72) Inventors: Shreesh NARASIMHA, Charlotte, NC (US); Yan SUN, San Diego, CA (US)

(21) Appl. No.: 19/067,240

(22) Filed: Feb. 28, 2025

(51) Int. Cl. H01L 23/528; H01L 23/522; H10D 30/00; H10D 30/43; H10D 62/10; H10D 84/85

(52) U.S. Cl. CPC H10W 20/427; H10D 30/43; H10D 30/502; H10D 62/121; H10D 84/851; H10W 20/42; H10W 20/43; H10W 20/435

(57) ABSTRACT

A chip includes a first diffusion region extending in a first direction, and a second diffusion region extending in the first direction, wherein the first diffusion region and the second diffusion region are stacked in a second direction perpendicular to the first direction. The chip also includes a first rail extending in the first direction, wherein the first diffusion region and the first rail are spaced apart in a third direction perpendicular to the first direction and the second direction. The chip also includes a third diffusion region extending in the first direction, wherein the third diffusion region is wider than the first diffusion region in the third direction, and a fourth diffusion region extending in the first direction, wherein the third diffusion region and the fourth diffusion region are stacked in the second direction.

### BACKGROUND

### Field

Aspects of the present disclosure relate generally to chip layout, and more particularly, to complementary field-effect transistors (CFETs).

### BACKGROUND

A chip includes many transistors for performing various functions on the chip. The transistors include p-type field-effect transistors (PFETs) and n-type field-effect transistors (NFETs). A PFET may be used in combination with an NFET to provide complementary transistors, which may be used in various circuits on the chip, including, for example, inverters, NAND gates, NOR gates, and other types of circuits.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a chip. The chip includes a first diffusion region extending in a first direction, and a second diffusion region extending in the first direction, wherein the first diffusion region and the second diffusion region are stacked in a second direction perpendicular to the first direction. The chip also includes a first rail extending in the first direction, wherein the first diffusion region and the first rail are spaced apart in a third direction perpendicular to the first direction and the second direction. The chip also includes a third diffusion region extending in the first direction, wherein the third diffusion region is wider than the first diffusion region in the third direction, and a fourth diffusion region extending in the first direction, wherein the third diffusion region and the fourth diffusion region are stacked in the second direction.

A second aspect relates to a chip. The chip includes a first rail extending in a first direction, a first track extending in the first direction, and a second track extending in the first direction, wherein the first rail is between the first track and the second track in a second direction perpendicular to the first direction. The chip also includes a first diffusion region extending in the first direction, wherein the first rail extends over the first diffusion region, and a second diffusion region extending in the first direction, wherein the first diffusion region and the second diffusion region are stacked in a third direction perpendicular to the first direction and the second direction. The chip also includes a first vertical connector extending in the third direction and coupled to the first track, and a second vertical connector extending in the third direction and coupled to the second track.

### BRIEF DESCRIPTION OF THE DRAWINGS

FIG. 1A shows a side view of an example of a chip including a transistor and multiple layers according to certain aspects of the present disclosure.

FIG. 1B shows a perspective view of the transistor implemented with a FinFET according to certain aspects of the present disclosure.

FIG. 1C shows a perspective view of the transistor implemented with a gate-all-around FET according to certain aspects of the present disclosure.

FIG. 1D shows a side view of the chip of FIG. 1A further including multiple backside layers according to certain aspects of the present disclosure.

FIG. 1E shows a side view of the chip of FIG. 1D further including a via disposed between a backside contact and a backside metal layer according to certain aspects of the present disclosure.

FIG. 2 shows a top view of an exemplary layout of cells including complementary transistors according to certain aspects of the present disclosure.

FIG. 3A shows a perspective view of an exemplary complementary field-effect transistor (CFET) structure according to certain aspects of the present disclosure.

FIG. 3B shows a perspective view of the CFET structure of FIG. 3A in which gates of the CFET structure are shown in phantom according to certain aspects of the present disclosure.

FIG. 4 shows a perspective view of an exemplary routing structure for providing power and signal routing for the CFET structure according to certain aspects of the present disclosure.

FIG. 5A shows a top view of an example of power routing and signal routing using the routing structure according to certain aspects of the present disclosure.

FIG. 5B shows a bottom view of an example of power routing and signal routing using the routing structure according to certain aspects of the present disclosure.

FIG. 5C shows a top view of an example of cells sharing a supply rail according to certain aspects of the present disclosure.

FIG. 6A shows a cross-sectional view taken along a first cross-section line in FIG. 5A according to certain aspects of the present disclosure.

FIG. 6B shows a cross-sectional view taken along a second cross-section line in FIG. 5A according to certain aspects of the present disclosure.

FIG. 6C shows a cross-sectional view taken along a third cross-section line in FIG. 5A according to certain aspects of the present disclosure.

FIG. 6D shows the cross-sectional view of FIG. 6C further including a via disposed between a vertical connector and a backside track according to certain aspects of the present disclosure.

FIG. 7 shows a circuit schematic of an exemplary NAND gate that may be implemented with the CFET structure using the routing structure according to certain aspects of the present disclosure.

FIG. 8A shows a perspective view of an exemplary CFET structure including wide diffusion regions according to certain aspects of the present disclosure.

FIG. 8B shows a perspective view of the CFET structure of FIG. 3A in which gates of the CFET structure are shown in phantom according to certain aspects of the present disclosure.

FIG. 9A shows a perspective view of an exemplary routing structure for providing power and signal routing for the CFET structure of FIGS. 8A and 8B according to certain aspects of the present disclosure.

FIG. 9B shows a side view of the exemplary routing structure of FIG. 9A according to certain aspects of the present disclosure.

FIG. 10A shows a top view of an example of power routing and signal routing using the routing structure of FIGS. 9A and 9B according to certain aspects of the present disclosure.

FIG. 10B shows a bottom view of an example of power routing and signal routing using the routing structure of FIGS. 9A and 9B according to certain aspects of the present disclosure.

FIG. 11A shows a cross-sectional view taken along a first cross-section line in FIG. 10A according to certain aspects of the present disclosure.

FIG. 11B shows a cross-sectional view taken along a second cross-section line in FIG. 10A according to certain aspects of the present disclosure.

FIG. 11C shows a cross-sectional view taken along a third cross-section line in FIG. 10A according to certain aspects of the present disclosure.

FIG. 11D shows the cross-sectional view of FIG. 11C further including vias disposed between vertical connectors and backside tracks according to certain aspects of the present disclosure.

FIG. 12A shows a first cross-sectional view in which the CFET structure and the routing structure are used to implement an inverter according to certain aspects of the present disclosure.

FIG. 12B shows a second cross-sectional view in which the CFET structure and the routing structure are used to implement the inverter according to certain aspects of the present disclosure.

FIG. 13 shows a circuit schematic of the inverter according to certain aspects of the present disclosure.

FIG. 14 shows a top view of an exemplary layout of cells arranged in rows according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

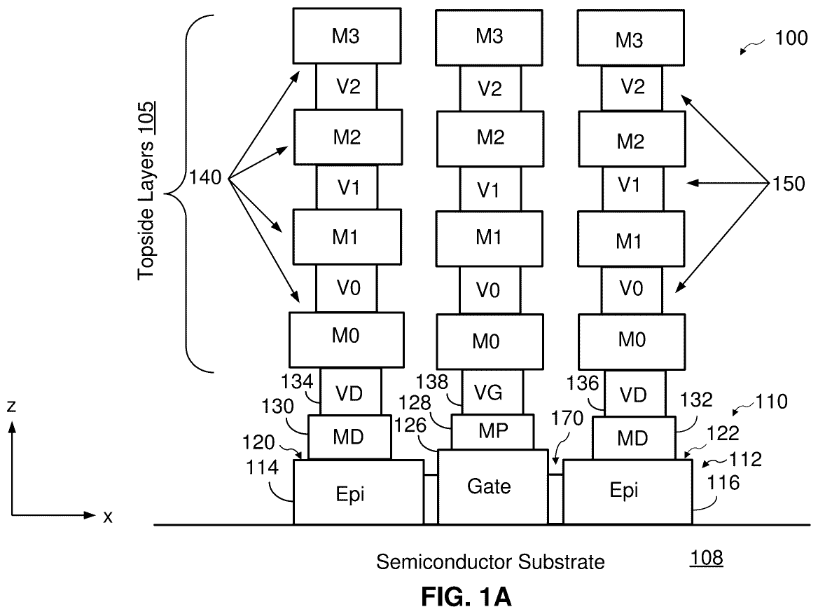

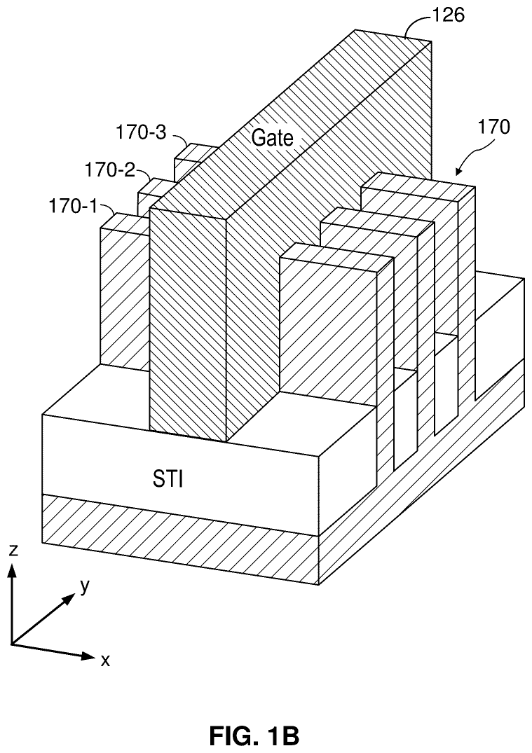

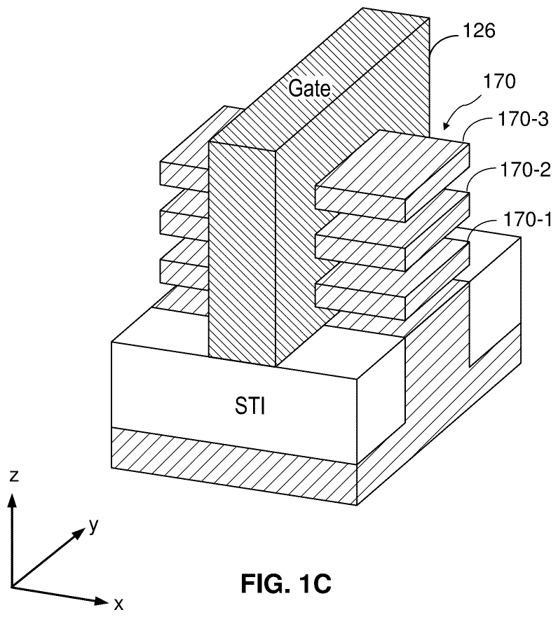

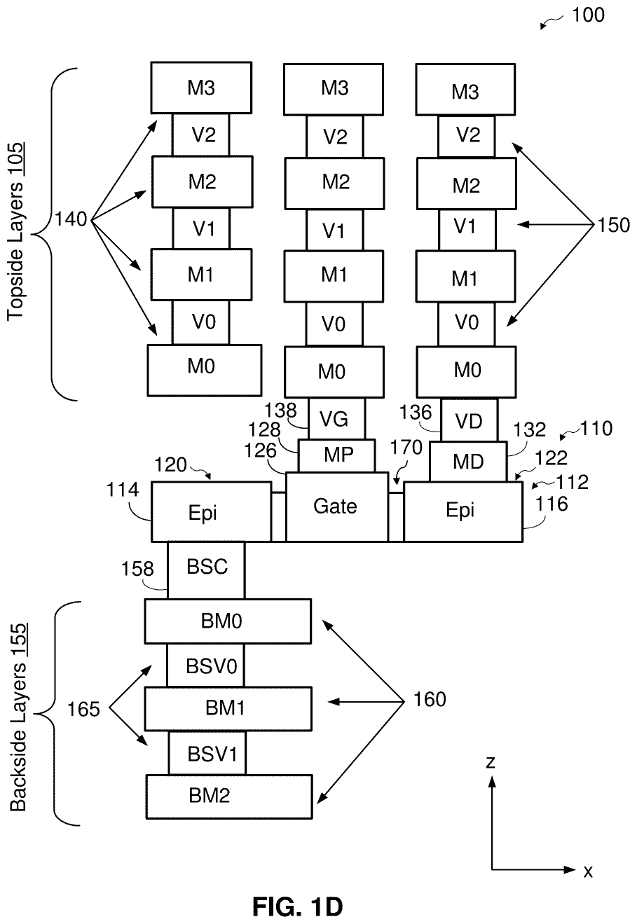

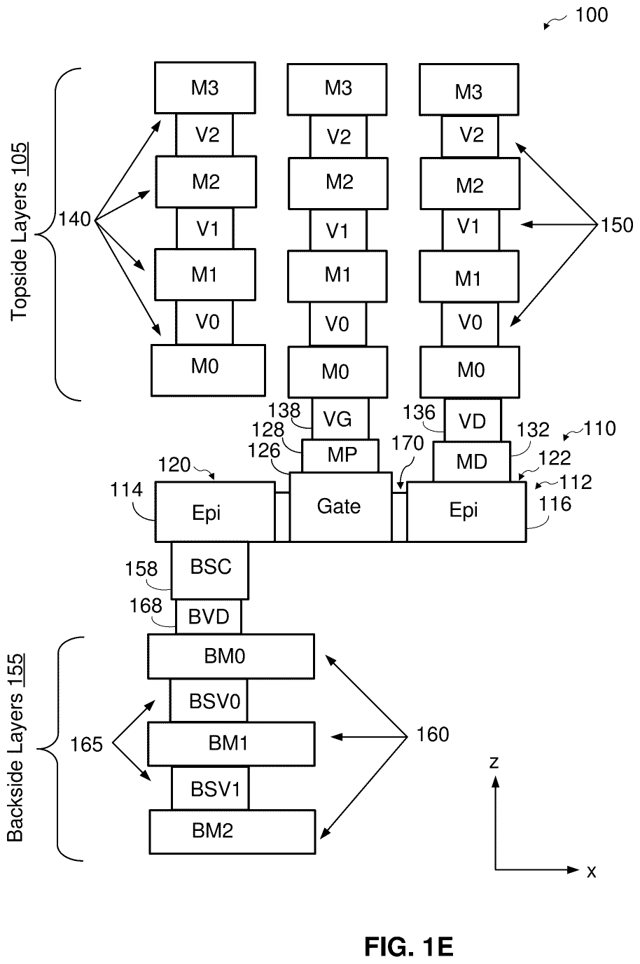

FIG. 1A shows a side view of an example of a chip 100 (e.g., a die) including a transistor 110 and multiple topside layers 105 (also referred to as frontside layers) according to certain aspects. Although one transistor 110 is shown in FIG. 1A for simplicity, it is to be appreciated that the chip 100 includes many transistors. As discussed further below, the transistor 110 may be implemented using a gate-all-around field effect transistor (FET) process, a fin field-effect transistor (FinFET) process, or another type of process. The topside layers 105 are above the transistor 110 in the z direction shown in FIG. 1A. The transistor 110 and the topside layers 105 may be formed on a semiconductor substrate 108 (e.g., silicon substrate).

In the example shown in FIG. 1A, the transistor 110 includes a diffusion region 112 and a gate 126 on the diffusion region 112. The diffusion region 112 may also be referred to as an oxide diffusion region, an active region, active diffusion, active (RX), or another term. The gate 126 may be formed on the diffusion region 112, and may include a gate metal (e.g., a high-k metal gate (HKMG)), polysilicon, and/or another gate material. The diffusion region 112 includes one or more channels 170 extending in the x direction in FIG. 1A, where the x direction is perpendicular to the z direction. As used herein, a “channel” is a structure that conducts current between a source and a drain of a transistor.

For a gate-all-around FET process, the diffusion region 112 may correspond to an area of the chip 100 where one or more nanosheets are formed, in which the gate 126 is formed around a portion of the one or more nanosheets to provide the one or more channels 170. In this example, portions of the one or more nanosheets outside of the gate 126 may be cut and epi layers may be coupled to opposite sides of the one or more channels 170, as discussed further below.

For the example of a FinFET process, the gate 126 may surround each of the one or more channels 170 on three sides. In this regard, FIG. 1B shows a perspective view in which the one or more channels 170 include channels 170-1, 170-2, and 170-3 where each of the channels 170-1, 170-2, and 170-3 is surrounded on three sides by the gate 126. In this example, each of the channels 170-1, 170-2, and 170-3 is orientated vertically, and the channels 170-1, 170-2, and 170-3 are spaced apart from one another in the y direction. The channels for a FinFET process may also be referred to as fins. In certain aspects, the chip 100 may include shallow trench isolation (STI) to reduce leakage between devices on the chip 100. In some implementations, the STI may be omitted.

For the example of a gate-all-around FET process, the gate 126 may surround each of the one or more channels 170 (also referred as ribbons) on four sides. In this regard, FIG. 1C shows a perspective view in which the one or more channels 170 include channels 170-1, 170-2, and 170-3 where each of the channels 170-1, 170-2, and 170-3 is surrounded on four sides by the gate 126. Each of the channels 170-1, 170-2, and 170-3 may include a nanosheet, a nanowire, or the like. In this example, the channels 170-1, 170-2, and 170-3 are stacked vertically and are spaced apart from one another in the z direction. However, it is to be appreciated that the present disclosure is not limited to this example.

Returning to FIG. 1A, the transistor 110 may include a first epitaxial (epi) layer 114 and a second epi layer 116 in which the gate 126 is disposed between the first epi layer 114 and the second epi layer 116. The first epi layer 114 is coupled to the one or more channels 170 on one side of the gate 126 to provide a first source/drain 120. The second epi layer 116 is coupled to the one or more channels 170 on the other side of the gate 126 to provide a second source/drain 122. An epi layer may also be referred to as simply epi or another term. As used herein, the term “source/drain” means a source, a drain, or both a source and a drain.

As shown in FIG. 1A, the first epi layer 114 and the second epi layer 116 are located on opposite sides of the gate 126. Each of the first epi layer 114 and the second epi layer 116 may include epitaxially grown or deposited silicon, a silicon-based material (e.g., silicon-germanium), or any combination thereof. In this example, the gate 126 controls the conductivity between the first source/drain 120 and the second source/drain 122 based on a voltage applied to the gate 126. The transistor 110 may include a first spacer (not shown in FIG. 1A) between the gate 126 and the first epi layer 114 and a second spacer (not shown in FIG. 1A) between the gate 126 and the second epi layer 116. A spacer may also be referred to as a sidewall spacer or another term.

In this example, the chip 100 includes a first contact 130 formed on a top surface of the first source/drain 120 and a second contact 132 formed on a top surface of the second source/drain 122. A top surface may also be referred to as a frontside surface. The contacts 130 and 132 may be formed (i.e., patterned) from a contact layer using, for example, lithographic and etching processes. Each of the contacts 130 and 132 may be referred to as a metal-diffusion (MD) contact, contact active (CA), or another term. Each of the contacts 130 and 132 may include cobalt (Co), tungsten (W), molybdenum (Mo), another conductive material, or any combination thereof.

The chip 100 may also include a gate contact 128 formed on the gate 126. The gate contact 128 may be referred to as a metal-poly (MP) contact or another term. The gate contact 128 may be omitted in some implementations.

In this example, the topside layers 105 include metal layers 140 (also referred to as a metal stack). The metal layers 140 may be patterned (e.g., using lithography and etching) to provide signal routing for the transistor 110 and other transistors (not shown in FIG. 1A) integrated on the chip 100. The metal layers 140 may also be patterned to form a power distribution network including supply rails for distributing power to the transistor 110 and other transistors integrated on the chip 100. A supply rail may also be referred to as a power rail or another term.

In the example in FIG. 1A, the bottom-most metal layer among the metal layers 140 is referred to as metal layer M0. The metal layer immediately above metal layer M0 is referred to as metal layer M1, the metal layer immediately above metal layer M1 is referred to as metal layer M2, the metal layer immediately above metal layer M2 is referred to as metal layer M3, and so forth. Although four metal layers 140 (i.e., M0 to M3) are shown in FIG. 1A for ease of illustration, it is to be appreciated that the topside layers 105 may include additional metal layers above metal layer M3. It is to be appreciated that the present disclosure is not limited to the nomenclature in which the bottom-most metal layer is referred to as metal layer M0. For instance, in another example, the bottom-most metal layer may be referred to as metal layer M1 instead of metal layer M0. Also, it is to be appreciated that one or more of the metal layers may be designated with a letter other than M in other examples. Accordingly, it is to be appreciated that the metal layers are not limited to the exemplary designations used in FIG. 1A.

The topside layers 105 also includes vias 150 that provide coupling between the metal layers 140. The vias 150 include vias V0, vias V1, and vias V3. In this example, the vias V0 provide coupling between metal layer M0 and metal layer M1, the vias V1 provide coupling between metal layer M1 and metal layer M2, and the vias V2 provide coupling between metal layer M2 and metal layer M3. In the example in FIG. 1A, the chip 100 also includes a via 138 disposed between the gate contact 128 and metal layer M0, in which the via 138 couples the gate contact 128 (and hence the gate 126) to metal layer M0. For implementations where the gate contact 128 is omitted, the via 138 may be disposed between the gate 126 and metal layer M0 without an intervening gate contact. In this example, the chip 100 also includes a via 134 disposed between the first contact 130 and metal layer M0, in which the via 134 couples the first contact 130 to metal layer M0. The chip 100 also includes a via 136 disposed between the second contact 132 and metal layer M0, in which the via 136 couples the second contact 132 to metal layer M0.

In certain aspects, the chip 100 may include backside layers to facilitate backside routing. In these aspects, most or all of the semiconductor substrate 108 is removed to form backside layers under the transistors (e.g., transistor 110) on the chip 100. As used here, “most” of the semiconductor substrate 108 means at least 90 percent of the semiconductor substrate 108. For example, after formation of the transistors and the topside layers 105, a carrier wafer (not shown) may be bonded to the top of the chip 100 for structural support. The chip 100 may then be flipped to expose the backside of the semiconductor substrate 108, and most or all of the semiconductor substrate 108 may be grounded and/or polished off (e.g., using chemical mechanical polishing (CMP)). Backside layers may then be formed under the transistors on the chip 100.

In this regard, FIG. 1D shows an example of backside layers 155 formed under the transistor 110. In this example, the backside layers 155 include backside metal layers 160. The backside metal layers 160 may be patterned (e.g., using lithography and etching) to form a backside power distribution network and/or backside signal routing. The backside power distribution network may include supply rails for distributing power to the transistor 110 and other transistors on the chip 100.

In the example in FIG. 1D, the top-most backside metal layer among the backside metal layers 160 is referred to as backside metal layer BM0. The backside metal layer immediately below backside metal layer BM0 is referred to as backside metal layer BM1, the backside metal layer immediately below backside metal layer BM1 is referred to as backside metal layer BM2, and so forth. Although three backside metal layers 160 (i.e., BM0 to BM2) are shown in FIG. 1D for ease of illustration, it is to be appreciated that the backside layers 155 may include additional metal layers below backside metal layer BM2.

In the example in FIG. 1D, the chip 100 includes a backside contact 158 formed on a bottom surface (i.e., backside surface) of the first source/drain 120. The backside contact 158 may be formed (i.e., patterned) from a backside contact layer (labeled “BSC”) using, for example, lithographic and etching processes. The backside contact 158 is used to couple the first source/drain 120 to backside metal layer BM0. In some implementations, the backside contact 158 may directly contact backside metal layer BM0, as shown in the example in FIG. 1D. In other implementations, the backside contact 158 may be coupled to backside metal layer BM0 through an intervening via. In this regard, FIG. 1E shows an example in which the chip 100 includes a backside via 168 (labeled “BVD”) disposed between the backside contact 158 and backside metal layer BM0. In this example, the backside via 168 provides a space between the backside contact 158 and backside metal layer BM0 in the z direction.

In the examples in FIG. 1D and FIG. 1E, the backside layers 155 include vias 165 that provide coupling between the backside metal layers 160. In this example, the vias 165 include a via BSV0 that provides coupling between backside metal layer BM0 and backside metal layer BM1, and a via BSV1 that provides coupling between backside metal layer BM1 and backside metal layer BM2.

In certain aspects, the topside metal layers 140 are patterned (e.g., using lithography and etching) to provide signal routing for the transistor 110 and other transistors (not shown in FIG. 1A) integrated on the chip 100, and the backside metal layers 160 are patterned to form a power distribution network including supply rails for distributing power to the transistor 110 and the other transistors integrated on the chip 100. Moving the power distribution network to the backside layers 155 helps reduce routing congestion compared with the case in which the topside layers 105 are used for both signal routing and power distribution. It is to be appreciated that, in some implementations, both the topside metal layers 140 and the backside metal layers 160 may be used for signal routing. In general, the present disclosure is not limited to a particular allocation of power routing and signal routing between the topside layers 105 and the backside layers 155.

Although one gate 126 is shown in FIGS. 1A to 1E, it is to be appreciated that the transistor 110 may include multiple gates arranged in parallel and coupled to one another (e.g., through metal layer M0 or another metal layer). A transistor with multiple gates may be referred to as a multi-gate transistor, a multi-finger transistor, or another term.

Transistors on the chip 100 may be organized into cells. Each cell may include one or more transistors that are arranged to implement a circuit (e.g., an inverter, a driver, a logic gate, combinational logic, a latch, a flip-flop, a bit cell, or another type of circuit). The layout of each cell may be specified (i.e., defined) in a standard cell library, which may be stored in a memory. The standard cell library may specify (i.e., define) the layout of each one of various cells that can be placed (i.e., laid out) on the chip 100 for a particular process. The chip 100 may include multiple instances of a particular cell defined in the standard cell library. The layout of each cell defined in the standard cell library may include the layout of gates, diffusion regions, and contacts in the cell. A cell that is defined in a standard cell library may also be referred to as a standard cell.

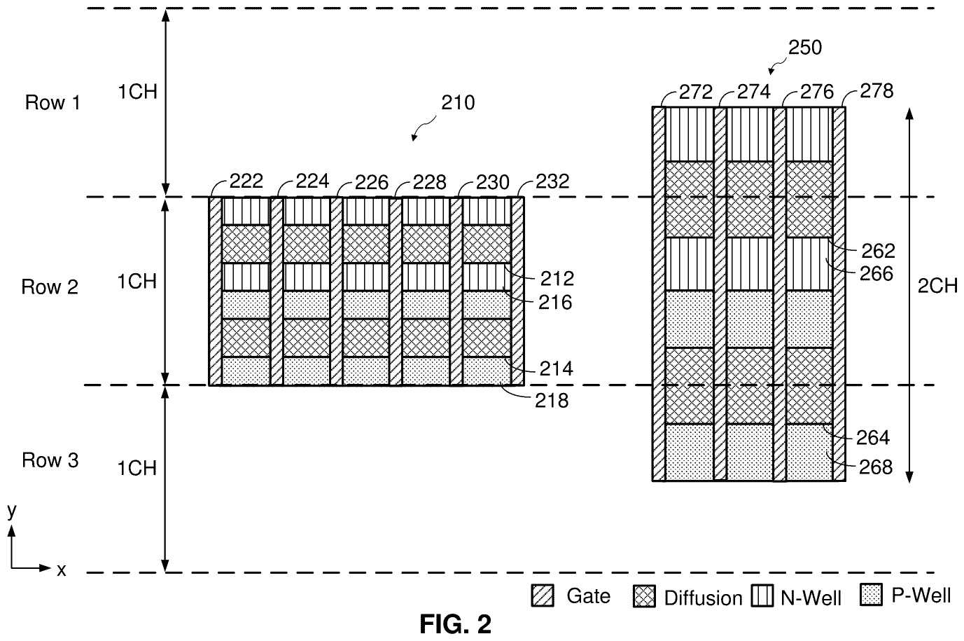

FIG. 2 shows a top view of an exemplary cell 210 including complementary transistors according to certain aspects of the present disclosure. The cell 210 may be used to implement a circuit that includes complementary transistors such as an inverter, a NAND gate, a NOR gate, or another type of circuit.

In this example, the cell 210 includes a first diffusion region 212 and a second diffusion region 214 extending in the x direction, in which the first diffusion region 212 and the second diffusion region 214 are placed (i.e., laid) side by side in the y direction. The first diffusion region 212 may be a p-type diffusion region and the second diffusion region 214 may be an n-type diffusion region to provide complementary transistors. Each of the diffusion regions 212 and 214 may include one or more channels extending in the x direction (e.g., one or more instances of the one or more channels 170). In this example, the chip 100 includes an n-well 216 and a p-well 218 formed in the substrate 108, in which the first diffusion region 212 is formed over the n-well 216 and the second diffusion region 214 is formed over the p-well 218.

The cell 210 also includes gates 224, 226, 228, and 230 extending in the y direction and spaced apart from one another in the x direction. Each of the gates 224, 226, 228, and 230 may include a gate metal (e.g., a high-k metal gate (HKMG)), polysilicon, and/or another gate material. The cell 210 may include additional gates 222 and 232 spaced apart from the gates 224, 226, 228, and 230 in the x direction (e.g., at a uniform pitch). The additional gates 222 and 232 may used as dummy gates (also known as non-functional gates) or used to implement additional transistors. In other implementations, the additional gates 222 and 232 may be replaced with diffusion breaks (e.g., single diffusion breaks or double diffusion breaks).

In this example, the first diffusion region 212 is a p-type diffusion region to provide one or more PFETs and the second diffusion region 214 is an n-type diffusion region to provide one or more NFETs. Thus, the diffusion regions 212 and 214 (which are placed side by side) provide the cell 210 with complementary transistors. In the example shown in FIG. 2, the first diffusion region 212 includes sources/drains separated by the gates 224, 226, 228, and 230 and the second diffusion region 214 includes sources/drains separated by the gates 224, 226, 228, and 230. Each source/drain may include an epi layer (e.g., an instance of epi layer 114 or 116). As used herein, sources/drains is the plural form of source/drain.

Multiple instances of the cell 210 may be arranged (i.e., laid out) in rows on the chip 100. In the regard, FIG. 2 shows an example of three rows including a first row (labeled “Row 1”), a second row (labeled “Row 2”), and a third row (labeled “Row 3”). In this example, the cell 210 has a cell height of one row (labeled “1CH”) and is placed in the second row. Although not shown in FIG. 2, it is to be appreciated that instances of the cell 210 also be placed in the first row and the third row. As used herein, “cell height” is the dimension of a cell in the y direction.

The chip 100 may also include rails (not shown in FIG. 2) formed in metal layer M0 for distributing power to the cell 210. For example, the rails may extend in the x direction and may be placed along the boundaries of the rows. The chip 100 may also include signal routing (not shown in FIG. 2) formed in metal layer M0 for routing signals to and from the cell 210.

FIG. 2 also shows an example of a cell 250 including a first diffusion region 262 and a second diffusion region 264 having wider widths than the first diffusion region 212 and the second diffusion region 214, respectively. In this example, the wider diffusion widths provides the cell 250 with higher performance (e.g., larger drive strength) than the cell 210. For example, the cell 250 may be used in a critical signal path where a larger drive strength is desired (e.g., to meet timing requirements in the critical signal path). As discussed further below, the cell 250 has a cell height (labeled “2CH”) that is double the cell height (labeled “1CH”) of the cell 210 due to the wider diffusion regions 262 and 264.

In this example, the first diffusion region 262 and the second diffusion region 264 extend in the x direction and are placed (i.e., laid) side by side in the y direction. The first diffusion region 262 may be a p-type diffusion region and the second diffusion region 264 may be an n-type diffusion region to provide complementary transistors. Each of the diffusion regions 262 and 264 may include one or more channels extending in the x direction (e.g., one or more instances of the one or more channels 170). In the example shown in FIG. 2, the chip 100 includes an n-well 266 and a p-well 268 formed in the substrate 108, in which the first diffusion region 262 is formed over the n-well 266 and the second diffusion region 264 is formed over the p-well 268. As shown in FIG. 2, the n-well 266 extends across half of the second row and half of the first row in the y direction, and the p-well 268 extend across half of the second row and half of the third row in the y direction.

The cell 250 also includes gates 274 and 276 extending in the y direction and spaced apart from one another in the x direction. Each of the gates 274 and 276 may include a gate metal (e.g., a high-k metal gate (HKMG)), polysilicon, and/or another gate material. The cell 250 may include additional gates 272 and 278 spaced apart from the gates 274 and 276 in the x direction (e.g., at a uniform pitch). The additional gates 272 and 278 may be used as dummy gates or used to implement additional transistors. In other implementations, the additional gates 272 and 278 may be replaced with diffusion breaks (e.g., single diffusion breaks or double diffusion breaks).

In this example, the first diffusion region 262 is a p-type diffusion region to provide one or more PFETs and the second diffusion region 264 is an n-type diffusion region to provide one or more NFETs. Thus, the diffusion regions 262 and 264 provide the cell 250 with complementary transistors. In the example shown in FIG. 2, the first diffusion region 262 includes sources/drains separated by the gates 274 and 276 and the second diffusion region 264 includes sources/drains separated by the gates 274 and 276. Each source/drain may include an epi layer (e.g., an instance of epi layer 114 or 116).

As discussed above, the cell 250 has a cell height (labeled “2CH”) that is double the cell height (labeled “1CH”) of the cell 210 due to the wider diffusion regions 262 and 264. Thus, the cell height of the cell 250 spans the height of two rows, as shown in FIG. 2. In this example, the cell 250 extend across half of the first row, the entire second row, and half of the third row in the y direction. This is done to place the first diffusion region 262 over the n-well 266 and the second diffusion region 264 over the p-well 268, as shown in FIG. 2. This placement of the cell 250 leaves the upper half of the first row adjacent to the cell 250 empty and leaves the lower half of the third row adjacent to the cell 250 empty. In this example, the empty spaces in the first row and the third row due to the placement of the cell 250 may be filled with filler cells (not shown). As used herein, a “filler cell” is a cell that performs no logic function and is used to fill an empty space between cells (e.g., to meet certain design rule checks for the process used to fabricate the chip). Because of the empty spaces in the first row and the third row left by the cell 250, a height of three rows may need to be allocated for the cell 250.

In this example, each of the cells 210 and 250 includes complementary transistors that are arranged side by side in the y direction.

In certain aspects, complementary transistors may include a PFET and an NFET that are stacked vertically in the z direction. Stacking the PFET and the NFET vertically reduces cell height in the y direction compared with the side-by-side arrangement of the PFET and the NFET illustrated in FIG. 2. The reduced cell height allows a larger number of cells to be placed on the chip 100.

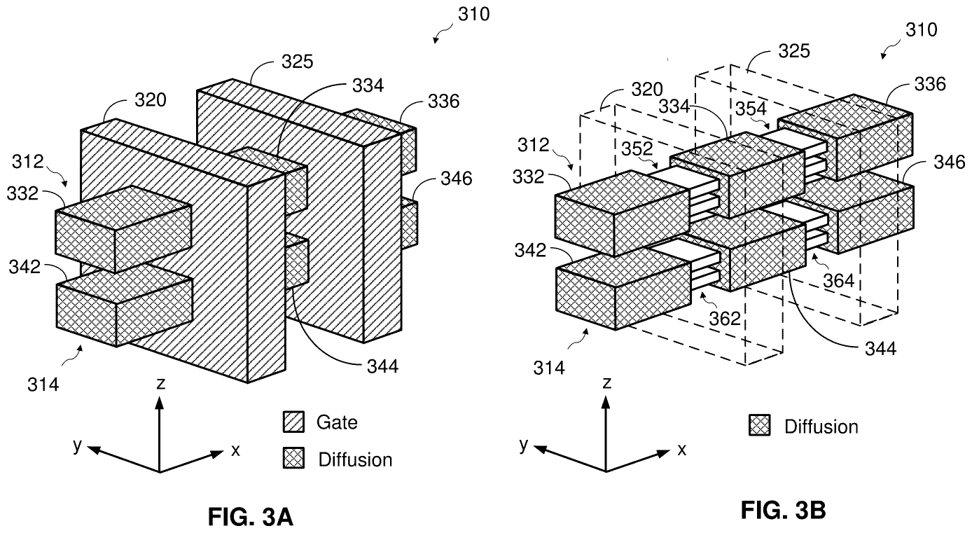

In this regard, FIG. 3A shows a perspective view of a complementary field-effect transistor (CFET) structure 310 with a stacked P-N architecture according to certain aspects. As discussed further below, the CFET structure 310 provides stacked complementary transistors. The CFET structure 310 may be used to implement a circuit that includes complementary transistors such as an inverter, a NAND gate, a NOR gate, or another type of circuit.

The CFET structure 310 includes a first diffusion region 312 extending in the x direction and a second diffusion region 314 extending in the x direction. The first diffusion region 312 and the second diffusion region 314 are stacked vertically in the z direction, in which the first diffusion region 312 and the second diffusion region 314 are spaced apart in the z direction. In the example in FIG. 3A, the first diffusion region 312 and the second diffusion region 314 are aligned in the y direction. The first diffusion region 312 may be a p-type diffusion region and the second diffusion region 314 may be an n-type diffusion region to provide complementary transistors. However, it is to be appreciated that the present disclosure is not limited to this example. In other implementations, the first diffusion region 312 may be an n-type diffusion region and the second diffusion region 314 may be a p-type diffusion region.

The CFET structure 310 also includes a first gate 320 and a second gate 325, in which each of the gates 320 and 325 extends in the y direction and the z direction. The gates 320 and 325 are spaced apart from one another in the x direction. Each of the gates 320 and 325 may include a gate metal (e.g., a high-k metal gate (HKMG)), polysilicon, and/or another gate material. It is to be appreciated that the positions of the diffusion regions 312 and 314 with respect to the gates 320 and 325 in the y direction and the z direction are not limited to the example shown in FIG. 3A.

In the example in FIG. 3A, the first diffusion region 312 includes a first source/drain 332 to the left of the first gate 320 in the x direction, a second source/drain 334 between the gates 320 and 325, and a third source/drain 336 to the right of the second gate 325 in the x direction. Each of the first source/drain 332, the second source/drain 334, and the third source/drain 336 may include a respective epitaxial (epi) layer. It is to be appreciated that the first source/drain 332, the second source/drain 334, and the third source/drain 336 may have shapes that differ from the exemplary shapes shown in FIG. 3A.

In this example, the first diffusion region 312 may include one or more channels 352 passing through the first gate 320 and one or more channels 354 passing through the second gate 325, as shown in FIG. 3B (which shows the gates 320 and 325 in phantom). In the example shown in FIG. 3B, the one or more channels 352 are coupled between the first source/drain 332 and the second source/drain 334, and the one or more channels 354 are coupled between the second source/drain 334 and the third source/drain 336. The one or more channels 352 and the one or more channels 354 may include nanosheets, nanowires, fins, or other types of channels.

In the example in FIG. 3A, the second diffusion region 314 includes a fourth source/drain 342 to the left of the first gate 320 in the x direction, a fifth source/drain 344 between the gates 320 and 325, and a sixth source/drain 346 to the right of the second gate 325 in the x direction. Each of the fourth source/drain 342, the fifth source/drain 344, and the sixth source/drain 346 may include a respective epi layer. It is to be appreciated that the fourth source/drain 342, the fifth source/drain 344, and the sixth source/drain 346 may have shapes that differ from the exemplary shapes shown in FIG. 3A.

In this example, the second diffusion region 314 may include one or more channels 362 passing through the first gate 320 and one or more channels 364 passing through the second gate 325, as shown in FIG. 3B (which shows the gates 320 and 325 in phantom). In the example shown in FIG. 3B, the one or more channels 362 are coupled between the fourth source/drain 342 and the fifth source/drain 344, and the one or more channels 364 are coupled between the fifth source/drain 344 and the sixth source/drain 346. The one or more channels 362 and the one or more channels 364 may include nanosheets, nanowires, fins, or other types of channels.

In this example, the vertically stacked diffusion regions 312 and 314 provide the CFET structure 310 with at least one pair of PFET and NFET that are vertically stacked. When the CFET structure 310 is included in a cell, the vertically stacked PFET and NFET reduce the height of the cell 210 in the y direction compared with the side-by-side P-N arrangement illustrated in FIG. 2.

However, area efficient power routing and signal routing for the CFET structure 310 is challenging, which may prevent the maximum cell height reduction potential of the CFET structure 310 from being realized. For example, a large challenge with signal routing for the CFET structure 310 is providing P-N coupling (i.e., coupling between a source/drain of a PFET and a source/drain of an NFET). Accordingly, techniques for providing more area efficient routing for the CFET structure 310 are desirable.

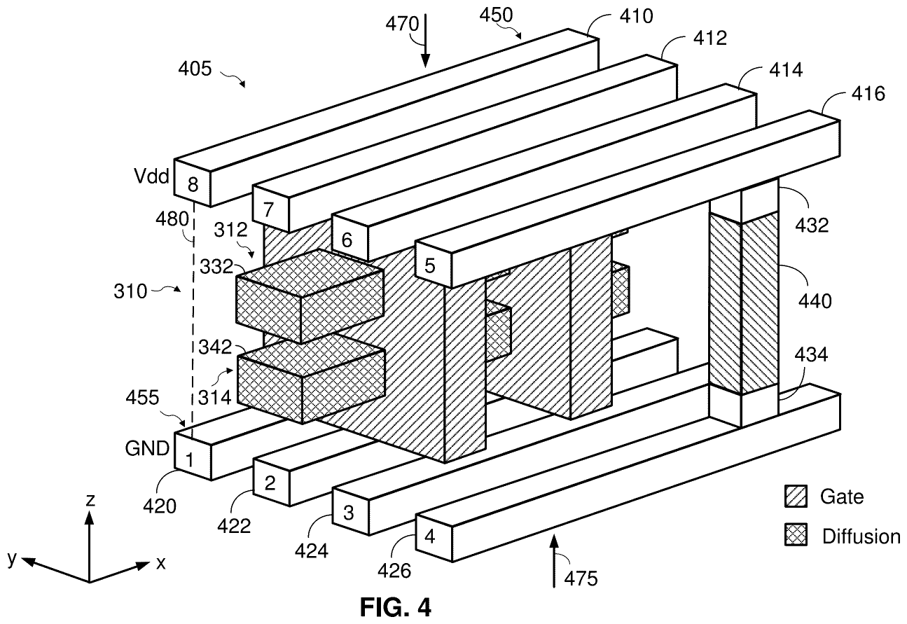

FIG. 4 shows a perspective view of a routing structure 405 for providing efficient power routing and signal routing for the CFET structure 310 according to certain aspects. The routing structure 405 includes a set of topside tracks 410, 412, 414, and 416 above the CFET structure 310. Each of the topside tracks 410, 412, 414, and 416 extends in the x direction. The topside tracks 410, 412, 414, and 416 are spaced apart from one another in the y direction. In certain aspects, the topside tracks 410, 412, 414, and 416 are in metal layer M0.

The routing structure 405 also includes a set of backside tracks 420, 422, 424, and 426 below (i.e., under) the CFET structure 310. Each of the backside tracks 420, 422, 424, and 426 extends in the x direction. The backside tracks 420, 422, 424, and 426 are spaced apart from one another in the y direction. In certain aspects, the backside tracks 420, 422, 424, and 426 are in backside metal layer BM0.

In the example in FIG. 4, each of the topside tracks 410, 412, 414, and 416 and each of the backside tracks 420, 422, 424, and 426 is elongated and extends in the lengthwise direction.

In this example, the topside track 410 and the backside track 420 are used as rails for routing power to the CFET structure 310. For example, the topside track 410 (labeled 8) may be used as a supply rail 450 for providing a supply voltage Vdd, and the backside track 420 (labeled 1) may be used as a ground rail 455, or vice versa. In the example in FIG. 4, the supply rail 450 and the ground rail 455 are aligned in the y direction. In other words, the supply rail 450 and the ground rail 455 are in-line vertically in this example. For the example where the CFET structure 310 is located in a standard cell, the supply rail 450 and the ground rail 455 may be located on an edge 480 of the cell (indicated by the dashed vertical line in FIG. 4). As discussed further below, this feature allows the supply rail 450 and the ground rail 455 to be shared with another cell in an adjacent row for improved area efficiency.

As discussed further below, the first diffusion region 312 may be coupled to the supply rail 450 through one or more topside contacts (e.g., contact layer MD in FIGS. 1A, 1D, and 1E) and one or more vias (e.g., via VD in FIGS. 1A, 1D, and 1E). The second diffusion region 314 may be coupled to the ground rail 455 through one or more backside contacts (e.g., backside contact layer BSC in FIGS. 1D and 1E) and one or more vias (e.g., via BVD in FIG. 1E).

In the example in FIG. 4, the routing structure 405 also includes a vertical connector 440 extending in the z direction. The vertical connector 440 may be coupled between the topside track 416 (labeled 5) and the backside track 426 (labeled 4). As discussed further below, the vertical connector 440 facilitates P-N coupling for the CFET structure 310. In the example shown in FIG. 4, the routing structure 405 includes a first via 432 disposed between a top surface of the vertical connector 440 and the topside track 416, and a second via 434 disposed between a bottom surface of the vertical connector 440 and the backside track 426. Thus, in this example, the vertical connector 440 is coupled to the topside track 416 through the first via 432 and coupled to the backside track 426 through the second via 434. As discussed further below, the vias 432 and 434 provide coupling flexibility for the vertical connector 440. It is to be appreciated that the vertical connector 440 is not limited to the exemplary location shown in FIG. 4, and that the vertical connector 440 may be placed at other locations between the topside track 416 and the backside track 426 in the x direction.

In this example, the topside track 412 (labeled 7) and the topside track 414 (labeled 6) are available for signal routing, and the backside track 422 (labeled 2) and the backside track 424 (labeled 3) are available for signal routing. For example, the topside tracks 412 and 414 may be used for input signal routing and the backside tracks 422 and 424 may be used for signal routing within a cell. However, it is to be appreciated that the tracks 412, 414, 422, and 424 are not limited to this example.

In this example, a p-well and an n-well are not present since most or all of the substrate 108 is removed for backside processing in this example. Thus, in this example, the placement of the diffusion regions 312 and 314 are not restricted by the layout of a p-well and an n-well.

Exemplary features of the routing structure 405 will now be discussed using an example in which the CFET structure 310 implements a NAND gate. However, it is to be appreciated that the routing structure 405 and the CFET structure 310 are not limited to a NAND gate, and that the CFET structure 310 may be used to implement other types of circuits.

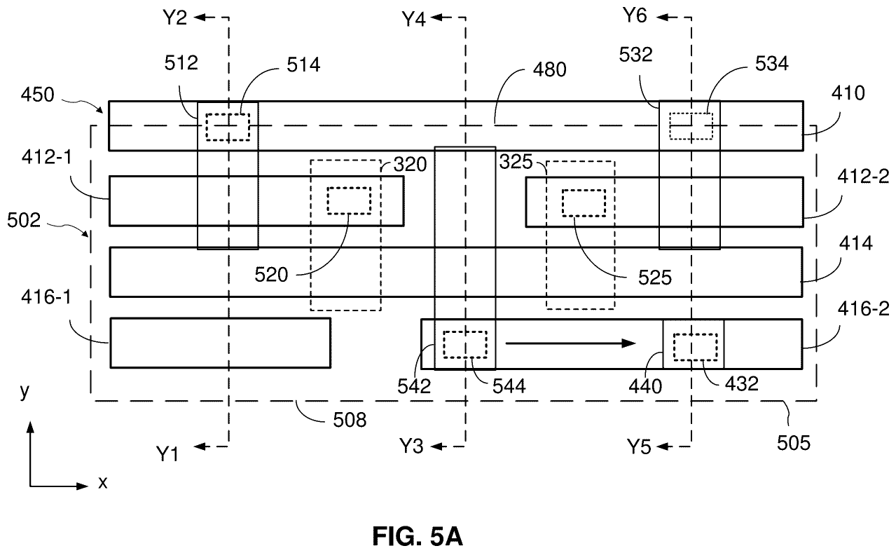

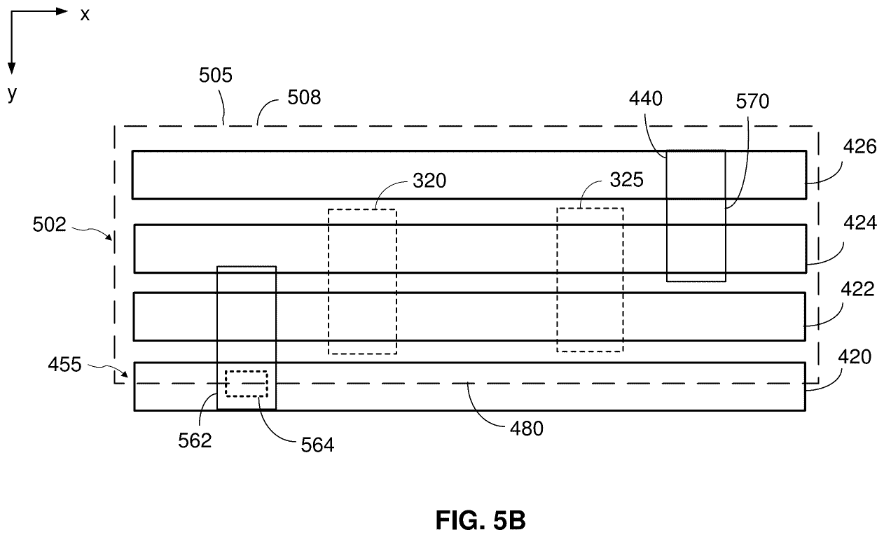

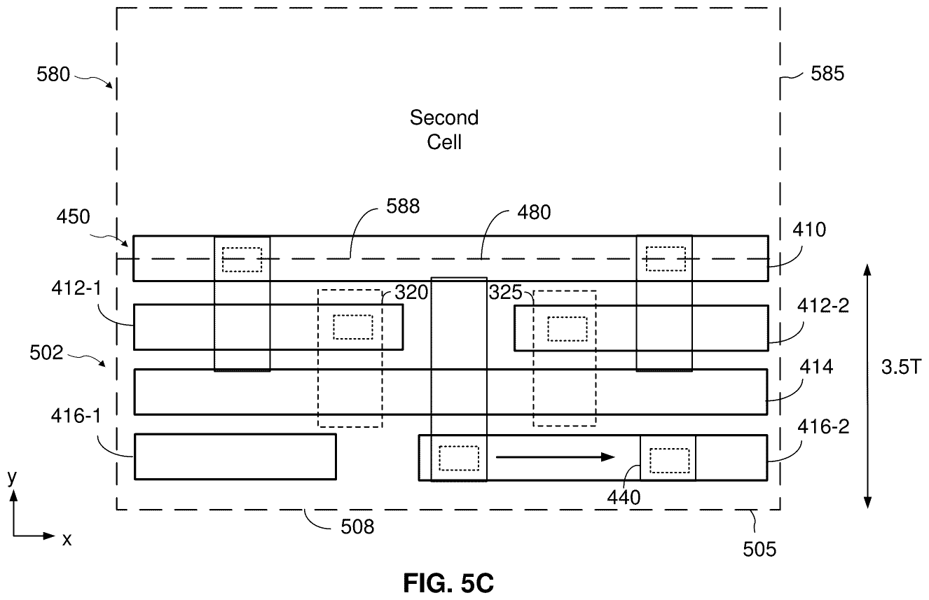

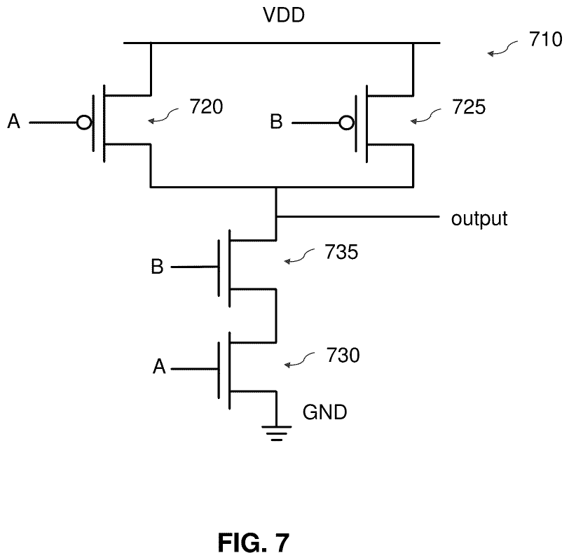

FIG. 5A shows a top view of the topside tracks 410, 412, 414, and 416 and FIG. 5B shows a bottom view of the backside tracks 420, 422, 424, and 426 for the example in which the CFET structure 310 implements the NAND gate. A circuit schematic of the NAND gate is provided in FIG. 7. The top view shown in FIG. 5A is a view of the topside tracks 410, 412, 414, and 416 looking down from the top in the direction 470 shown in FIG. 4, and the bottom view shown in FIG. 5B is a view of the backside tracks 420, 422, 424, and 426 looking up from the bottom in the direction 475 shown in FIG. 4. Note that the topside tracks 410, 412, 414, and 416 are transparent in FIG. 5A in order to show structures located below the topside tracks 410, 412, 414, and 416, and the backside tracks 420, 422, 424, and 426 are transparent in FIG. 5B in order to show structures located above the backside tracks 420, 422, 424, and 426. In FIGS. 5A and 5B, vias are shown in dotted line and gates are shown in dashed line.

Referring to FIG. 5A, in this example, a first topside contact 512 is disposed on a top surface of the first source/drain 332 (shown in FIGS. 3A and 3B). The first topside contact 512 extends in the y direction under the supply rail 450 (e.g., the topside track 410). A via 514 disposed between the first topside contact 512 and the supply rail 450 couples the first topside contact 512 to the supply rail 450.

In this example, a second topside contact 532 is disposed on a top surface of the third source/drain 336 (shown in FIGS. 3A and 3B). The second topside contact 532 extends in the y direction under the supply rail 450 (e.g., the topside track 410). A via 534 disposed between the second topside contact 532 and the supply rail 450 couples the second topside contact 532 to the supply rail 450.

In this example, the topside track 412 is cut into a first input signal path 412-1 and a second input signal path 412-2. A via 520 disposed between the first input signal path 412-1 and the first gate 320 (shown in dashed line) couples the first input signal path 412-1 to the first gate 320. A via 525 disposed between the second input signal path 412-2 and the second gate 325 (shown in dashed line) couples the second input signal path 412-2 to the second gate 325. In this example, the first input signal path 412-1 provides a first input of the NAND gate and the second input signal path 412-2 provides a second input of the NAND gate.

A third topside contact 542 is disposed on a top surface of the second source/drain 334 (shown in FIGS. 3A and 3B). The third topside contact 542 extends in the y direction under the topside track 416. In the example in FIG. 5A, the topside track 416 is cut into a first portion 416-1 and a second portion 416-2, in which the second portion 416-2 provides an output signal path for the NAND gate. In this example, a via 544 disposed between the third topside contact 542 and the second portion 416-2 of the topside track 416 (i.e., the output signal path in this example) couples the third topside contact 542 to the second portion 416-2 of the topside track 416. In this example, the vertical connector 440 is coupled to the second portion 416-2 of the topside track 416 to provide P-N coupling, as discussed further below. In the shown in FIG. 5A, the vertical connector 440 is coupled to the second portion 416-2 of the topside track 416 through the first via 432 disposed between the second portion 416-2 of the topside track 416 and the vertical connector 440.

Referring to FIG. 5B, a first backside contact 562 is disposed on a bottom surface of the fourth source/drain 342 (shown in FIGS. 3A and 3B). The first backside contact 562 extends in the y direction above the ground rail 455 (e.g., the backside track 420). A via 564 disposed between the ground rail 455 and the first backside contact 562 couples the ground rail 455 to the first backside contact 562.

A second backside contact 570 is disposed on a bottom surface of the sixth source/drain 346 (shown in FIGS. 3A and 3B). The second backside contact 570 extends in the y direction and is coupled to the vertical connector 440. Thus, the second backside contact 570 is coupled to the output signal path (i.e., second portion 416-2 of the topside track 416 in this example) through the vertical connector 440 in this example.

In some implementations, the vertical connector 440 may also be coupled to the backside track 426 through the second via 434 (not shown in FIG. 5B). However, it is to be appreciated that the second via 434 may be omitted in other implementations. As discussed further below, the second via 434 allows a designer to control whether the vertical connector 440 is coupled to the backside track 426 by including or omitting the second via 434.

In certain aspects, the CFET structure 310 may be included in a standard cell 502. In this regard, FIGS. 5A and 5B shows an example of the cell boundary 505 of the cell 502 in dashed line. The cell boundary 505 includes the edge 480 discussed above and an edge 508 opposite the edge 480. In this example, the topside tracks 412, 414, and 416 and the backside tracks 426, 424, and 422 are located within the cell boundary 505 between the edges 480 and 508.

In the example shown in FIGS. 5A and 5B, the supply rail 450 and the ground rail 455 are located on the edge 480 of the cell boundary 505, in which the edge 480 extends in the x direction. Locating the supply rail 450 and the ground rail 455 on the edge 480 of the cell boundary 505 allows the supply rail 450 and the ground rail 455 to be shared with a neighboring cell located in an adjacent row for improved area efficiency.

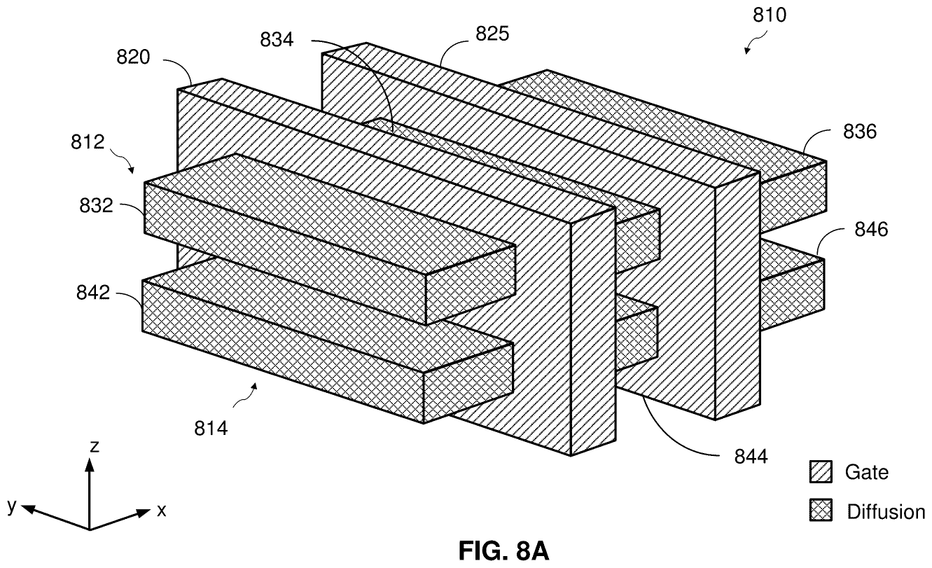

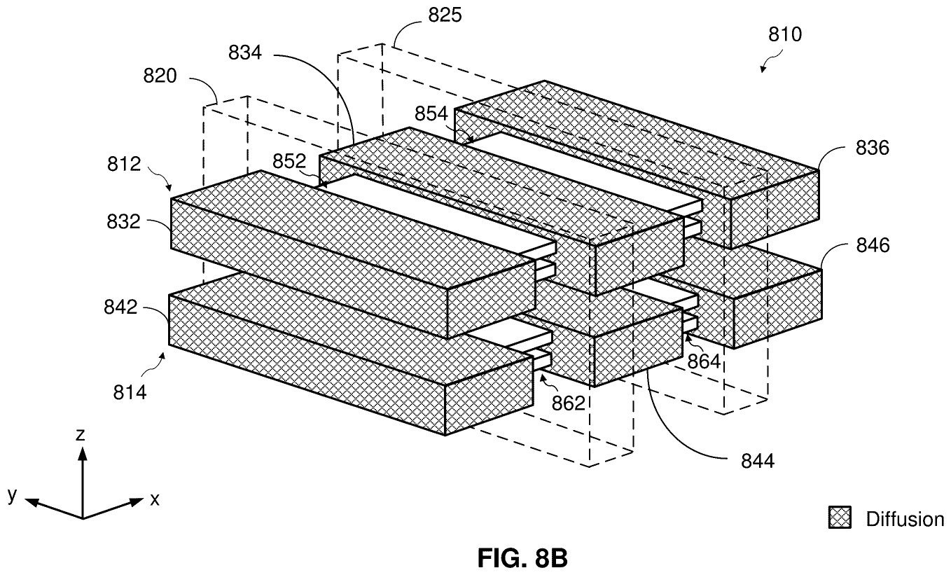

In this regard, FIG. 5C shows a top view of an example in which the cell 502 shares the supply rail 450 and the ground rail 455 with a second cell 580. The second cell 580 is located in a row that is adjacent to the row in which the cell 502 is located. In this example, the edge 588 of the cell boundary 585 of the second cell 580 abuts the edge 480 of the cell boundary 505 of the cell 502, and the supply rail 450 and the ground rail 455 (not shown in FIG. 8C) are located on both edges 588 and 480. As a result, the supply rail 450 overlaps both cells 502 and 580, and the ground rail 455 overlaps both cells 502 and 580. This allows both cells 502 and 580 to access the supply rail 450 and the ground rail 455 for receiving power. Sharing the supply rail 450 and the ground rail 455 between the cells 502 and 580 improves area efficiency compared with providing the cells 502 and 580 with separate supply rails and separate ground rails.

The second cell 580 may include a CFET structure (e.g., second instance of the CFET structure 310). The chip 100 may also include topside tracks (e.g., second instance of the topside tracks 412, 414, and 416), backside tracks (e.g., second instance of the backside tracks 422, 424, and 426), and a vertical connector (e.g., second instance of the vertical connector 440) to provide signal routing for the second cell 580. The arrangement of the topside tracks for the second cell 580 may be flipped in the y direction with respect to the arrangement of the topside tracks 412, 414, 416 for the cell 502. Also, the arrangement of the backside tracks for the second cell 580 may be flipped in the y direction with respect to the arrangement of the backside tracks 422, 424, and 426 for the cell 502 (shown in FIG. 5B).

In the example shown in FIG. 5C, the cell 502 has a cell height of 3.5T where T is the pitch of the topside tracks 410, 412, 414, and 416, and the pitch of the backside tracks 420, 422, 424, and 426. However, it is to be appreciated that the cell 502 is not limited to this example.

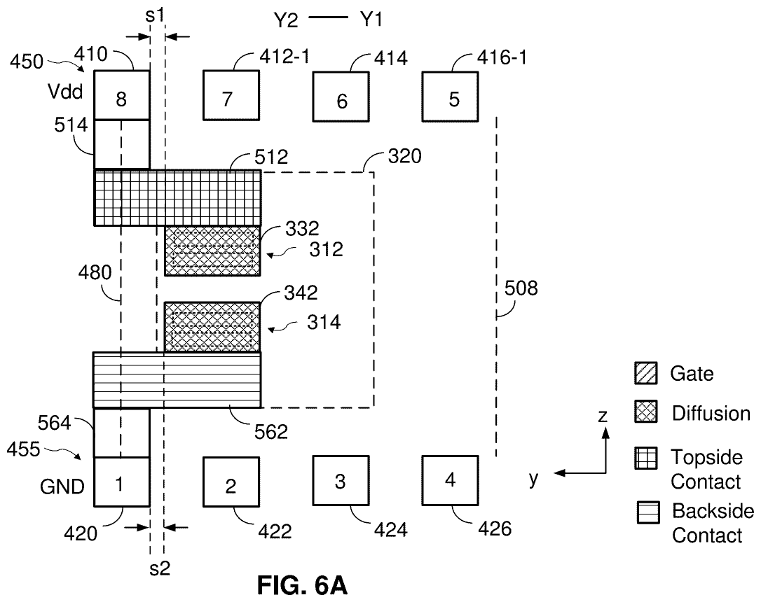

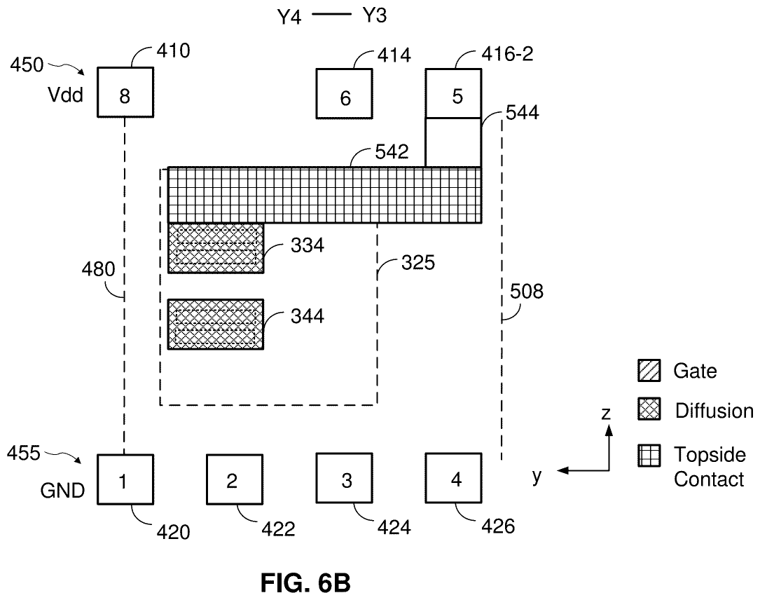

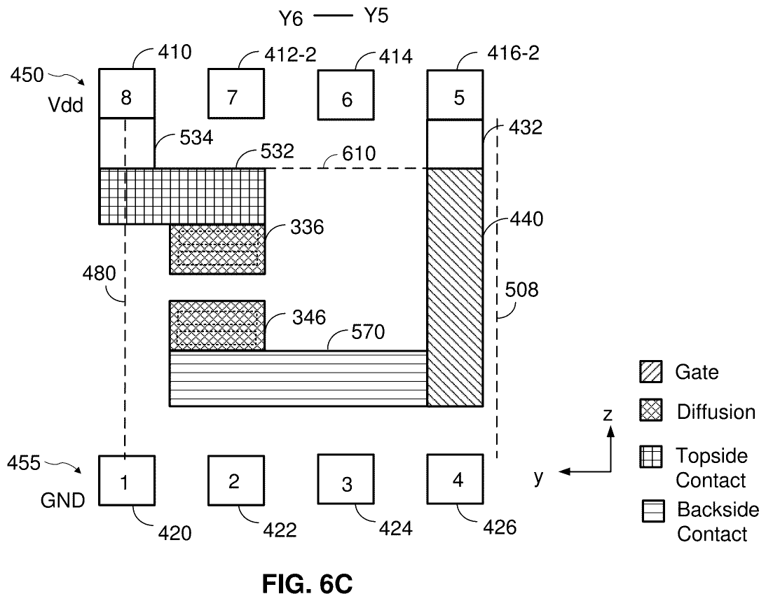

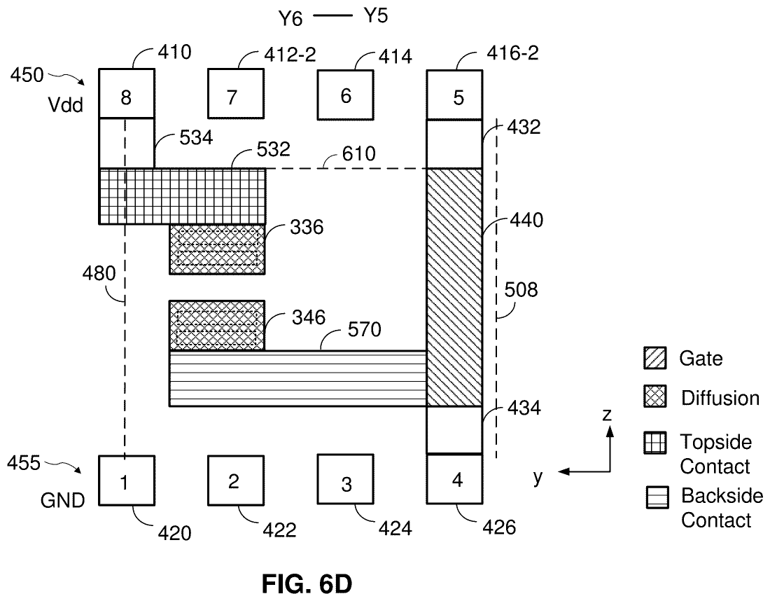

FIG. 6A shows a cross-sectional view taken along cross-section line Y2-Y1 in FIG. 5A. As shown in FIG. 6A, the first source/drain 332 is coupled to the supply rail 450 (e.g., topside track 410) through the first topside contact 512 and the via 514. The fourth source/drain 342 is coupled to the ground rail 455 (e.g., the backside track 420) through the first backside contact 562 and the via 564. Note that the cross-section line Y2-Y1 does not intersect the first gate 320. The first gate 320 is shown in dashed line in FIG. 6A to indicate the location of the first gate 320 in the y direction and the z direction.

As shown in FIG. 6A, the supply rail 450 and the ground rail 455 are in-line vertically at the edge 480 of the cell boundary 505. In other words, the supply rail 450 and the ground rail 455 are aligned in the y direction.

In this example, the supply rail 450 and the first diffusion region 312 are spaced apart in the y direction, and the ground rail 455 and the second diffusion region 314 are spaced apart in the y direction. In FIG. 6A, the space between the supply rail 450 and the first diffusion region 312 in the y direction is labeled s1, and the space between the ground rail 455 and the second diffusion region 314 in the y direction is labeled s2 where s2 may be equal to s1. In this example, spacing the diffusion regions 312 and 314 apart from the supply rail 450 and the ground rail 455 in the y direction allows the supply rail 450 and the ground rail 455 to be shared with diffusion regions in an adjacent cell (not shown) without the diffusion regions 312 and 314 interfering with the diffusion regions in the adjacent cell.

In the example shown in FIG. 6A, the first topside contact 512 extends in the y direction from the top surface of the first source/drain 332 to an area directly under the supply rail 450 to couple the first source/drain 332 to the supply rail 450 through the via 514. The first backside contact 562 extends from in the y direction from the bottom surface of the fourth source/drain 342 to an area directly above the ground rail 455 to couple the fourth source/drain 342 to the ground rail 455 through the via 564.

FIG. 6B shows a cross-sectional view taken along cross-section line Y4-Y3 in FIG. 5A. As shown in FIG. 6B, the second source/drain 334 is coupled to the output signal path (i.e., the second portion 416-2 of the topside track 416 in this example) through the third topside contact 542 and the via 544. The third topside contact 542 extends in the y direction from the top surface of the second source/drain 334 to an area directly below the second portion 416-2 of the topside track 416 to couple the second source/drain 334 to the second portion 416-2 of the topside track 416 through the via 544. Note that the cross-section line Y4-Y3 does not intersect the second gate 325. The second gate 325 is shown in dashed line in FIG. 6B to indicate the location of the second gate 325 in the y direction and the z direction.

FIG. 6C shows a cross-sectional view taken along cross-section line Y6-Y5 in FIG. 5A. As shown in FIG. 6C, the third source/drain 336 is coupled to the supply rail 450 (e.g., topside track 410) through the second topside contact 532 and the via 534. In this example, the second topside contact 532 extends in the y direction from the top surface of the third source/drain 336 to an area directly below the supply rail 450 to couple the third source/drain 336 to the supply rail 450 through the via 534.

Also, as shown in FIG. 6C, the sixth source/drain 346 is coupled to the vertical connector 440 through the second backside contact 570, in which the second backside contact 570 extends in the y direction from the bottom surface of the sixth source/drain 346 to the vertical connector 440. In this example, the vertical connector 440 is used to couple the sixth source/drain 346 to the output signal path (i.e., the second portion 416-2 of the topside track 416 in this example).

In the examples shown in FIG. 6C, the second via 434 is omitted. FIG. 6D shows another example in which the vertical connector 440 is also coupled to the backside track 426 through the second via 434. Thus, the examples in FIGS. 6C and 6D illustrate that the second via 434 allows a designer to control whether the vertical connector 440 is coupled to the backside track 426 by including or omitting the second via 434. In these examples, the vertical connector 440 is coupled to the backside track 426 when the second via 434 is included (shown in FIG. 6D), and the vertical connector 440 is not coupled to the backside track 426 when the second via 434 is omitted (shown in FIG. 6C).

In the example shown in FIGS. 6C and 6D, the bottom of the vertical connector 440 is flush (i.e., planar) with the bottom of the second backside contact 570, and the second via 434 (shown in FIG. 6D) has the same height in the z direction as the via 564 (shown in FIG. 6A) used to couple the first backside contact 562 to the ground rail 455. This allows the vias 434 and 564 to be formed using the same process flow for process efficiency.

In the examples shown in FIGS. 6C and 6D, the first via 432 allows a designer to control whether the vertical connector 440 is coupled to the topside track 416 by including or omitting the first via 432. The vertical connector 440 is coupled to the topside track 416 when the first via 432 is included (shown in FIGS. 6C and 6D), and the vertical connector 440 is not coupled to the topside track 416 when the first via 432 is omitted (not shown).

In the examples shown in FIGS. 6C and 6D, the top of the vertical connector 440 is flush (i.e., planar) with the top of the second topside contact 532 (indicated by the line 610), and the first via 432 has the same height in the z direction as the via 534 (shown in FIGS. 6C and 6D) and the via 514 (shown in FIG. 6A). This allows the vias 432, 534, and 514 to be formed using the same process flow for process efficiency.

FIG. 7 shows a circuit schematic of the NAND gate 710 implemented by the CFET structure 310 using the routing structure 405 in the example shown in FIGS. 5A, 5B, 6A, 6B, 6C, and 6D. However, it is to be appreciated that the CFET structure 310 is not limited to this example, and that the CFET structure 310 may implement other types of circuits using the routing structure 405.

In this example, the NAND gate 710 includes a first PFET 720, a second PFET 725, a first NFET 730, and a second NFET 735. The first PFET 720 and the second PFET 725 are coupled in parallel between the supply rail (e.g., topside track 410) and the output of the NAND gate 710 (e.g., the second portion 416-2 of the topside track 416), in which the sources of the first PFET 720 and the second PFET 725 are coupled to the supply rail, and the drains of the first PFET 720 and the second PFET 725 are coupled to the output. The gate (e.g., the first gate 320) of the first PFET 720 is coupled to the first input (labeled A in FIG. 7) and the gate (e.g., the second gate 325) of the second PFET 725 is coupled to the second input (e.g., labeled B in FIG. 7).

The first NFET 730 and the second NFET 735 are coupled in series between the output of the NAND gate 710 and the ground rail (e.g., backside track 420), in which the source of the first NFET 730 is coupled to the ground rail, the drain of the first NFET 730 is coupled to the source of the second NFET 735, and the drain of the second NFET 735 is coupled to the output (e.g., through the vertical connector 440). The gate (e.g., the first gate 320) of the first NFET 730 is coupled to the first input (labeled A in FIG. 7) and the gate (e.g., the second gate 325) of the second NFET 735 is coupled to the second input (labeled B in FIG. 7).

In this example, the first source/drain 332, the first gate 320, and the second source/drain 334 implement the source, the gate, and the drain, respectively, of the first PFET 720. The third source/drain 336, the second gate 325, and the second source/drain 334 implement the source, the gate, and the drain, respectively, of the second PFET 725. The fifth source/drain 344, the first gate 320, and the fourth source/drain 342 implement the drain, the gate, and the source of the first NFET 730. The sixth source/drain 346, the second gate 325, and the fifth source/drain 344 implement the drain, the gate, and the source of the second NFET 735.

In the example shown in FIGS. 5A and 5B, the vertical connector 440 is aligned with the second backside contact 570 and offset from the third topside contact 542 in the x direction. However, it is to be appreciated that the present disclosure is not limited to this example. For example, in some implementations, the vertical connector 440 may be offset from both the second backside contact 570 and the third topside contact 542 in the x direction. In this example, the second backside contact 570 may be coupled to the backside track 426 through a backside via (e.g., BVD in FIG. 1E) and the vertical connector 440 may be coupled between the tracks 416 and 426 through the vias 432 and 434, respectively.

FIG. 8A shows a perspective view of a CFET structure 810 including a first diffusion region 812 and a second diffusion region 814 having wider widths in the y direction than the first diffusion region 312 and the second diffusion region 314, respectively, of the CFET structure 310. For example, in some implementations, each of the diffusion regions 812 and 814 may be at least 1.5 times wider (e.g., between 1.5 and 6 times wider) than each of the diffusion regions 312 and 314 in the y direction. The wider diffusion widths provides the CFET structure 810 with higher performance (e.g., larger drive strength) than the CFET structure 310. For example, the CFET structure 810 may be used in a critical signal path where a larger drive strength is desired (e.g., to meet timing requirements in the critical signal path). As discussed further below, the CFET structure 810 may be included in a cell having a cell height that is double the cell height cell of the cell 502 including the CFET structure 310.

As shown in FIG. 8A, the first diffusion region 812 and the second diffusion region 814 are stacked vertically in the z direction, in which the first diffusion region 812 and the second diffusion region 814 are spaced apart in the z direction. In the example in FIG. 8A, the first diffusion region 812 and the second diffusion region 814 are aligned in the y direction. The first diffusion region 812 may be a p-type diffusion region and the second diffusion region 814 may be an n-type diffusion region to provide complementary transistors. However, it is to be appreciated that the present disclosure is not limited to this example. In other implementations, the first diffusion region 812 may be an n-type diffusion region and the second diffusion region 814 may be a p-type diffusion region.

The CFET structure 810 also includes a first gate 820 and a second gate 825, in which each of the gates 820 and 825 extends in the y direction and the z direction. The gates 820 and 825 are spaced apart from one another in the x direction. Each of the gates 820 and 825 may include a gate metal (e.g., a high-k metal gate (HKMG)), polysilicon, and/or another gate material. It is to be appreciated that the positions of the diffusion regions 812 and 814 with respect to the gates 820 and 825 in the y direction and the z direction are not limited to the example shown in FIG. 8A. In certain aspects, each of the gates 820 and 825 may be wider (e.g. at least 1.5 times wider) in the y direction than each of the gates 320 and 325 to accommodate the wider diffusion region widths.

In the example in FIG. 8A, the first diffusion region 812 includes a first source/drain 832 to the left of the first gate 820 in the x direction, a second source/drain 834 between the gates 820 and 825, and a third source/drain 836 to the right of the second gate 825 in the x direction. Each of the first source/drain 832, the second source/drain 834, and the third source/drain 836 may include a respective epitaxial (epi) layer. It is to be appreciated that the first source/drain 832, the second source/drain 834, and the third source/drain 836 may have shapes that differ from the exemplary shapes shown in FIG. 8A.

In this example, the first diffusion region 812 may include one or more channels 852 passing through the first gate 820 and one or more channels 854 passing through the second gate 825, as shown in FIG. 8B (which shows the gates 820 and 825 in phantom). In the example shown in FIG. 8B, the one or more channels 852 are coupled between the first source/drain 832 and the second source/drain 834, and the one or more channels 854 are coupled between the second source/drain 834 and the third source/drain 836. The one or more channels 852 and the one or more channels 854 may include nanosheets, nanowires, fins, or other types of channels. In certain aspects, each of the one or more channels 852 may be at least 1.5 times wider than each of the one or more channels 352 in the y direction and each of the one or more channels 854 may be at least 1.5 times wider than each of the one or more channels 354 in the y direction.

In the example in FIG. 8A, the second diffusion region 814 includes a fourth source/drain 842 to the left of the first gate 820 in the x direction, a fifth source/drain 844 between the gates 820 and 825, and a sixth source/drain 846 to the right of the second gate 825 in the x direction. Each of the fourth source/drain 842, the fifth source/drain 844, and the sixth source/drain 846 may include a respective epi layer. It is to be appreciated that the fourth source/drain 842, the fifth source/drain 844, and the sixth source/drain 846 may have shapes that differ from the exemplary shapes shown in FIG. 8A.

In this example, the second diffusion region 814 may include one or more channels 862 passing through the first gate 820 and one or more channels 864 passing through the second gate 825, as shown in FIG. 8B (which shows the gates 820 and 825 in phantom). In the example shown in FIG. 8B, the one or more channels 862 are coupled between the fourth source/drain 842 and the fifth source/drain 844, and the one or more channels 864 are coupled between the fifth source/drain 844 and the sixth source/drain 846. The one or more channels 862 and the one or more channels 864 may include nanosheets, nanowires, fins, or other types of channels. In certain aspects, each of the one or more channels 862 may be at least 1.5 times wider than each of the one or more channels 362 in the y direction and each of the one or more channels 864 may be at least 1.5 times wider than each of the one or more channels 364 in the y direction.

In this example, the vertically stacked diffusion regions 812 and 814 provide the CFET structure 810 with at least one pair of PFET and NFET that are vertically stacked. When the CFET structure 810 is included in a cell, the vertically stacked PFET and NFET reduce the height of the cell in the y direction compared with the side-by-side P-N arrangement illustrated in FIG. 2.

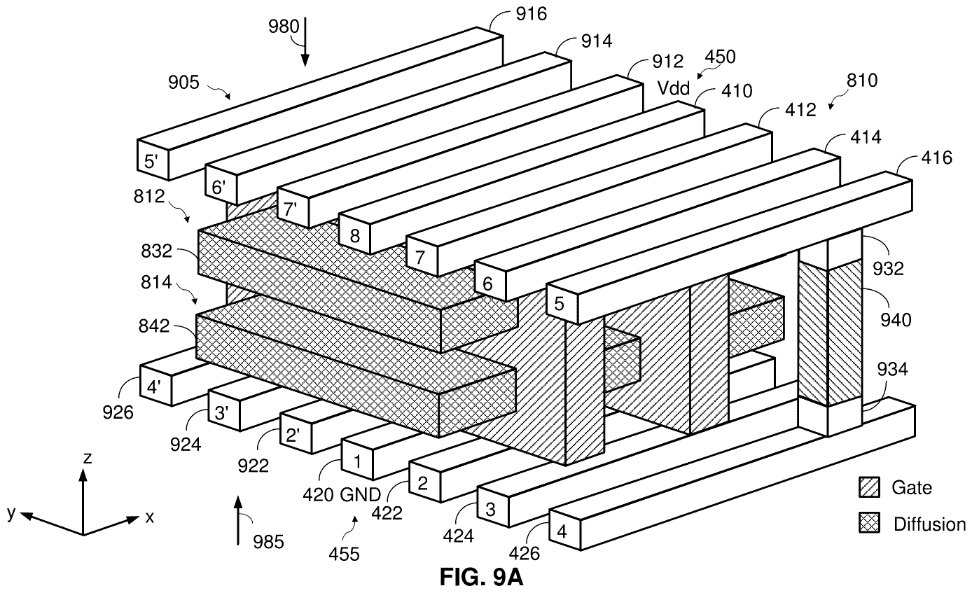

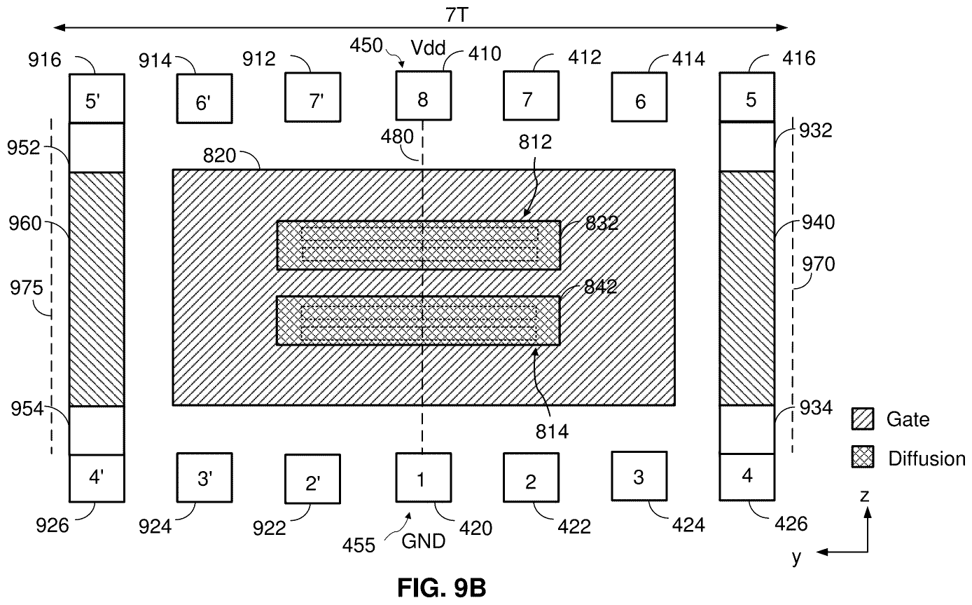

FIG. 9A shows a perspective view and FIG. 9B shows a side view of a routing structure 905 for providing efficient power routing and signal routing for the CFET structure 810 according to certain aspects. The routing structure 905 includes the topside tracks 410, 412, 414, and 416 discussed above. In addition, the routing structure 905 includes the topside tracks 912, 914, and 916, in which the topside tracks 912, 914, and 916 may be symmetric with the topside tracks 412, 414, and 416 about the topside track 410. Each of the topside tracks 410, 412, 414, 416, 912, 914, and 916 extends in the x direction. The topside tracks 410, 412, 414, 416, 912, 914, and 916 are above the CFET structure 810 and are spaced apart from one another in the y direction. In certain aspects, the topside tracks 410, 412, 414, 416, 912, 914, and 916 are in metal layer M0.

The routing structure 905 also includes backside tracks 420, 422, 424, and 426 discussed above. In addition, the routing structure 905 includes the backside tracks 922, 924, and 926, in which the backside tracks 922, 924, and 926 may be symmetric with the backside tracks 422, 424, and 426 about the backside track 420. Each of the backside tracks 420, 422, 424, 426, 922, 924, and 926 extends in the x direction, The backside tracks 420, 422, 424, 426, 922, 924, and 926 are below (i.e., under) the CFET structure 810 and are spaced apart from one another in the y direction. In certain aspects, the backside tracks 420, 422, 424, 426, 922, 924, and 926 are in backside metal layer BM0.

In the example in FIGS. 9A and 9B, each of the topside tracks 410, 412, 414, 416, 912, 914, and 916 and each of the backside tracks 420, 422, 424, 426, 922, 924, and 926 is elongated and extends in the lengthwise direction.

In this example, the topside track 410 and the backside track 420 are used as rails for routing power to the CFET structure 810. For example, the topside track 410 (labeled 8) may be used as the supply rail 450 for providing the supply voltage Vdd, and the backside track 420 (labeled 1) may be used as the ground rail 455, or vice versa. In the example in FIGS. 8A and 8B, the supply rail 450 and the ground rail 455 are aligned in the y direction. In other words, the supply rail 450 and the ground rail 455 are in-line vertically in this example.

As discussed further below, the first diffusion region 812 may be coupled to the supply rail 450 through one or more topside contacts (e.g., contact layer MD in FIGS. 1A, 1D, and 1E) and one or more vias (e.g., via VD in FIGS. 1A, 1D, and 1E). The second diffusion region 814 may be coupled to the ground rail 455 through one or more backside contacts (e.g., backside contact layer BSC in FIGS. 1D and 1E) and one or more vias (e.g., via BVD in FIG. 1E).

In the example in FIGS. 9A and 9B, the routing structure 905 also includes a first vertical connector 940 extending in the z direction. The first vertical connector 940 may be coupled between the topside track 416 (labeled 5) and the backside track 426 (labeled 4). The routing structure 905 includes a first via 932 disposed between a top surface of the first vertical connector 940 and the topside track 416, and a second via 934 disposed between a bottom surface of the first vertical connector 940 and the backside track 426. Thus, in this example, the first vertical connector 940 is coupled to the topside track 416 through the first via 932 and coupled to the backside track 426 through the second via 934. It is to be appreciated that the first vertical connector 940 is not limited to the exemplary location shown in FIG. 9A, and that the first vertical connector 940 may be placed at other locations between the topside track 416 and the backside track 426 in the x direction.

Referring to FIG. 9B (which shows a side view), the routing structure 905 also includes a second vertical connector 960 extending in the z direction. The second vertical connector 960 may be coupled between the topside track 916 (labeled 5′) and the backside track 926 (labeled 4′). The routing structure 905 includes a first via 952 disposed between a top surface of the second vertical connector 960 and the topside track 916, and a second via 954 disposed between a bottom surface of the second vertical connector 960 and the backside track 926. Thus, in this example, the second vertical connector 960 is coupled to the topside track 916 through the first via 952 and coupled to the backside track 926 through the second via 954. As shown in the example in FIG. 9B, the first vertical connector 940 and the second vertical connector 960 are located on opposite sides of the diffusion regions 812 and 814 in the y direction.

As discussed further below, the two vertical connectors (i.e., the first vertical connector 940 and the second vertical connector 960) may be used in parallel to lower resistance compared with using one vertical connector. The lower resistance helps the CFET structure 810 handle larger currents resulting from a larger drive strength of the CFET structure 810.

In this example, the topside track 412 (labeled 7), the topside track 414 (labeled 6), the topside track 912 (labeled 7′), and the topside track 914 (labeled 6′) may be available for signal routing, and the backside track 422 (labeled 2), the backside track 424 (labeled 3), the backside track 922 (labeled 2′), and the backside track 924 (labeled 3′) may be available for signal routing.

As shown in FIG. 9B, the CFET structure 810 may be placed between edges 970 and 975, where the edges 970 and 975 extend in the x direction. The edges 970 and 975 may be part of the boundary of a cell including the CFET structure 810, as discussed further below. In this example, the cell height of the cell including the CFET structure 810 is 7 T where T is the pitch of the topside tracks and the backside tracks. This is double the cell height of 3.5 T of the cell 502 including the CFET structure 310. However, it is to be appreciated that present disclosure is not limited to this example.

In this example, a p-well and an n-well are not present since most or all of the substrate 108 is removed for backside processing in this example. Thus, in this example, the placement of the diffusion regions 812 and 814 are not restricted by the layout of a p-well and an n-well.

Exemplary features of the routing structure 905 will now be discussed using an example in which the CFET structure 810 implements a NAND gate. However, it is to be appreciated that the routing structure 905 and the CFET structure 810 are not limited to a NAND gate, and that the CFET structure 810 may be used to implement other types of circuits.

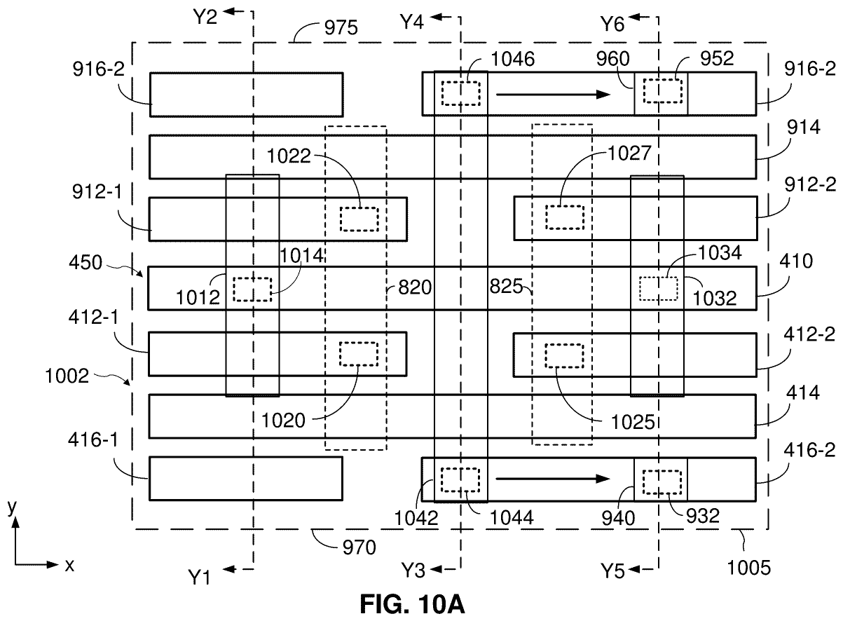

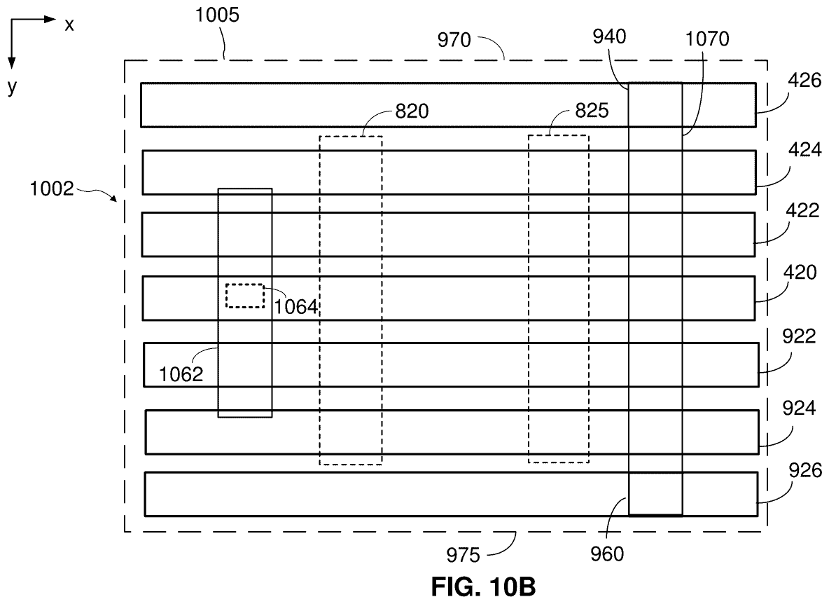

FIG. 10A shows a top view of the topside tracks 410, 412, 414, 416, 912, 914, and 916 and FIG. 10B shows a bottom view of the backside tracks 420, 422, 424, 426, 922, 924, and 926 for the example in which the CFET structure 810 implements the NAND gate. A circuit schematic of the NAND gate is shown in FIG. 7 discussed above. In this example, the CFET structure 810 is within a cell 1002 having a cell height of 7 T. However, it is to be appreciated that the present disclosure is not limited to this example.

The top view shown in FIG. 10A is a view of the topside tracks 410, 412, 414, 416, 912, 914, and 916 looking down from the top in the direction 980 shown in FIG. 9A, and the bottom view shown in FIG. 10B is a view of the backside tracks 420, 422, 424, 426, 922, 924, and 926 looking up from the bottom in the direction 985 shown in FIG. 9A. Note that the topside tracks 410, 412, 414, 416, 912, 914, and 916 are transparent in FIG. 10A in order to show structures located below the topside tracks 410, 412, 414, 416, 912, 914, and 916 and the backside tracks 420, 422, 424, 426, 922, 924, and 926 are transparent in FIG. 10B in order to show structures located above the backside tracks 420, 422, 424, 426, 922, 924, and 926. In FIGS. 10A and 10B, vias are shown in dotted line and gates are shown in dashed line.

Referring to FIG. 10A, in this example, a first topside contact 1012 is disposed on a top surface of the first source/drain 832 (shown in FIGS. 8A and 8B). The first topside contact 1012 extends in the y direction under the supply rail 450 (e.g., the topside track 410). A via 1014 disposed between the first topside contact 1012 and the supply rail 450 couples the first topside contact 1012 to the supply rail 450. Thus, in this example, the first source/drain 832 is coupled to the supply rail 450 through the first topside contact 1012 and the via 1014.

In this example, a second topside contact 1032 is disposed on a top surface of the third source/drain 836 (shown in FIGS. 8A and 8B). The second topside contact 1032 extends in the y direction under the supply rail 450 (e.g., the topside track 410). A via 1034 disposed between the second topside contact 1032 and the supply rail 450 couples the second topside contact 1032 to the supply rail 450. Thus, in this example, the third source/drain 836 is coupled to the supply rail 450 through the second topside contact 1032 and the via 1034.

In this example, the topside track 412 is cut into a first input signal path 412-1 and a second input signal path 412-2. A via 1020 disposed between the first input signal path 412-1 and the first gate 820 (shown in dashed line) couples the first input signal path 412-1 to the first gate 820. A via 1025 disposed between the second input signal path 412-2 and the second gate 825 (shown in dashed line) couples the second input signal path 412-2 to the second gate 825. In this example, the first input signal path 412-1 provides the first input (labeled “A” in FIG. 7) of the NAND gate and the second input signal path 412-2 provides the second input (labeled “B” in FIG. 7) of the NAND gate.

In the example in FIG. 10A, the topside track 912 may also be cut into a first input signal path 912-1 and a second input signal path 912-2, in which the first input signal 912-1 is coupled to the first gate 820 by the via 1022 and the second input signal path 912-2 is coupled to the second gate 825 by the via 1027. In this example, the input signal paths 412-1 and 912-1 may be coupled (e.g., through metal layer M1) and the input signal paths 412-2 and 912-2 may be coupled (e.g., through metal layer M1).

It is to be appreciated that, in certain aspects, the input for the first gate 820 may be implemented using just one of the input signal paths 412-1 and 912-1 and the input for the second gate 825 may be implemented using just one of the input signal paths 412-2 and 912-2. In these aspects, any one of the following via combinations may be used for the inputs of the gates 820 and 825: vias 1020 and 1025, vias 1020 and 1027, vias 1022 and 1025, and vias 1022 and 1027.

A third topside contact 1042 is disposed on a top surface of the second source/drain 834 (shown in FIGS. 8A and 8B). The third topside contact 1042 extends in the y direction under the topside track 416. In the example in FIG. 10A, the topside track 416 is cut into a first portion 416-1 and a second portion 416-2, in which the second portion 416-2 provides an output signal path for the NAND gate. In this example, a via 1044 disposed between the third topside contact 1042 and the second portion 416-2 of the topside track 416 (i.e., the output signal path in this example) couples the third topside contact 1042 to the second portion 416-2 of the topside track 416. In this example, the first vertical connector 940 is coupled to the second portion 416-2 of the topside track 416 to provide P-N coupling, as discussed further below. In the shown in FIG. 10A, the first vertical connector 940 is coupled to the second portion 416-2 of the topside track 416 through the first via 932.

In the example in FIG. 10A, the third topside contact 1042 may also extend under the topside track 916. In the example in FIG. 10A, the topside track 916 is cut into a first portion 916-1 and a second portion 916-2, in which the second portion 916-2 may be coupled to the second portion 416-2 of the track 416 (e.g., through metal layer M1). In this example, a via 1046 disposed between the third topside contact 1042 and the second portion 916-2 of the topside track 916 couples the third topside contact 1042 to the second portion 916-2 of the topside track 916. In this example, the second vertical connector 960 is coupled to the second portion 916-2 of the topside track 916 to provide P-N coupling, as discussed further below. In the shown in FIG. 10A, the second vertical connector 960 is coupled to the second portion 916-2 of the topside track 916 through the first via 952.

Referring to FIG. 10B, a first backside contact 1062 is disposed on a bottom surface of the fourth source/drain 842 (shown in FIGS. 8A and 8B). The first backside contact 1062 extends in the y direction above the ground rail 455 (e.g., the backside track 420). A via 1064 disposed between the ground rail 455 and the first backside contact 1062 couples the ground rail 455 to the first backside contact 1062. Thus, in this example, the fourth source/drain 842 is coupled to the ground rail 455 through the first backside contact 1062 and the via 1064.

A second backside contact 1070 is disposed on a bottom surface of the sixth source/drain 846 (shown in FIGS. 8A and 8B). The second backside contact 870 extends in the y direction and is coupled to the first vertical connector 940 and the second vertical connector 960. Thus, the second backside contact 1070 is coupled to the output signal paths (i.e., second portion 416-2 of the topside track 416 and the second portion 916-2 of the topside track 916 in this example) through the vertical connectors 940 and 960 in this example.

In some implementations, the first vertical connector 940 may also be coupled to the backside track 426 through the second via 934 (not shown in FIG. 10B) and/or the second vertical connector 960 may be coupled to the backside track 926 through the second via 954. However, it is to be appreciated that the via 934 and/or the via 954 may be omitted in other implementations.

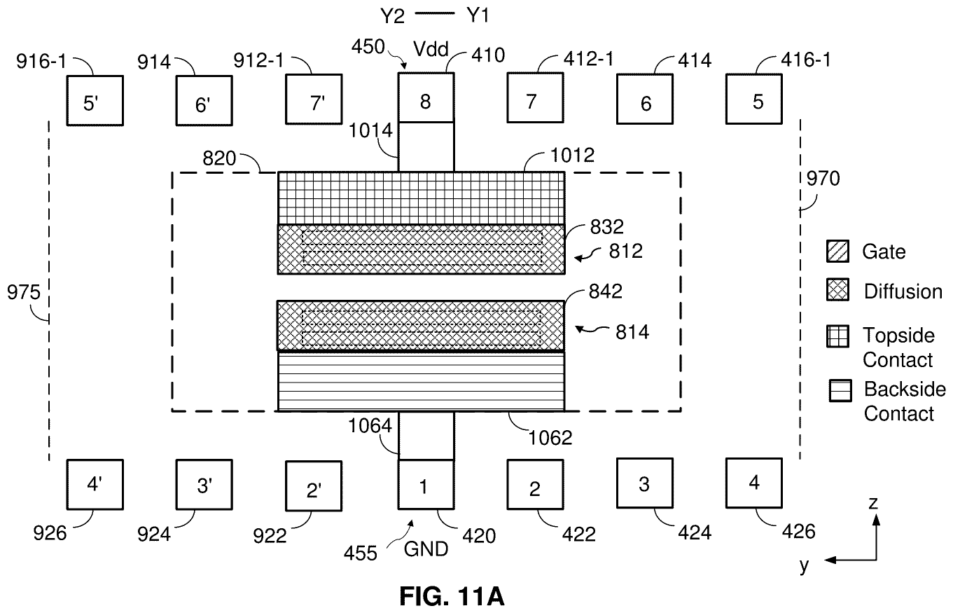

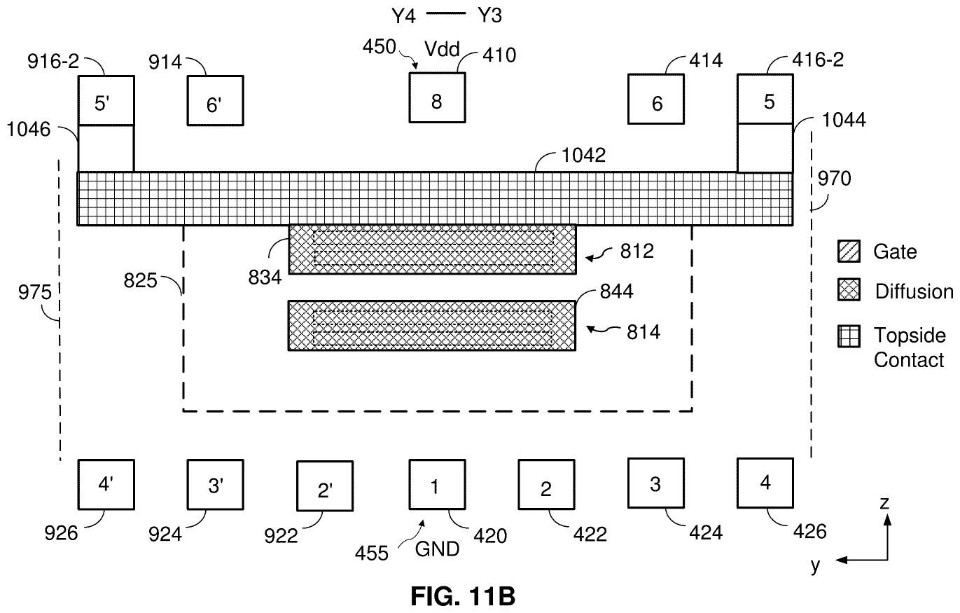

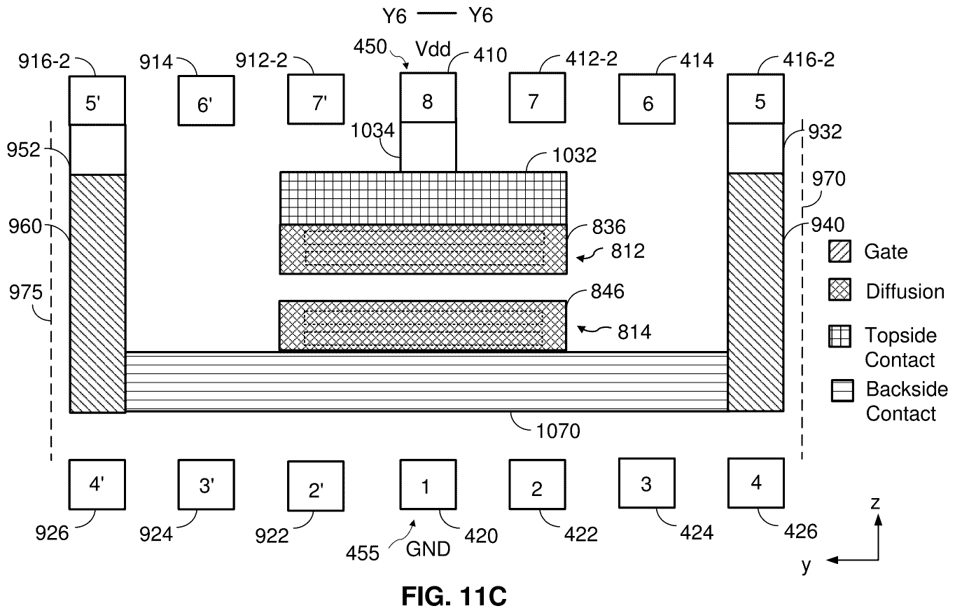

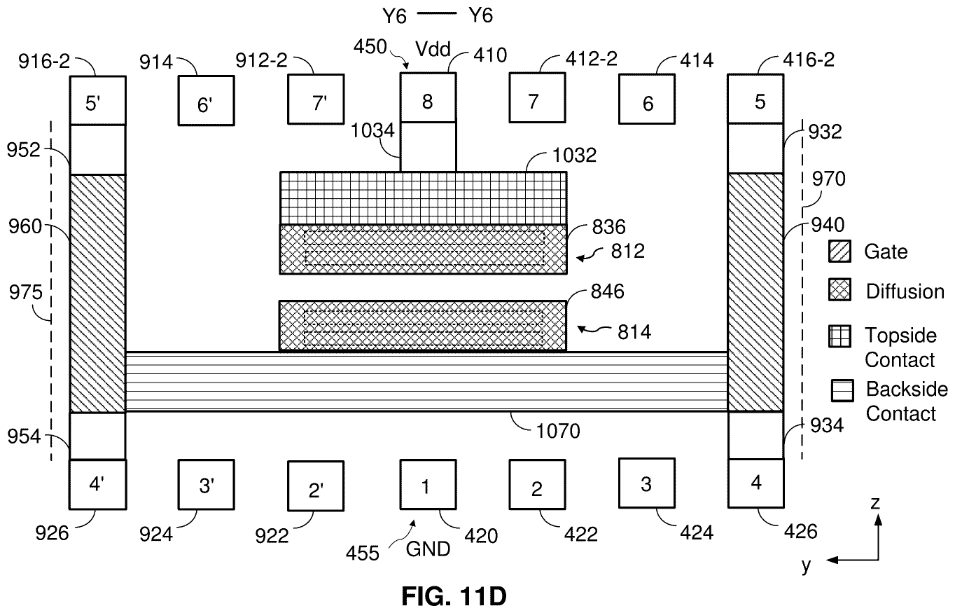

FIG. 11A shows a cross-sectional view taken along cross-section line Y2-Y1 in FIG. 10A. As shown in FIG. 11A, the first source/drain 832 is coupled to the supply rail 450 (e.g., topside track 410) through the first topside contact 1012 and the via 1014. The fourth source/drain 842 is coupled to the ground rail 455 (e.g., the backside track 420) through the first backside contact 1062 and the via 1064. Note that the cross-section line Y2-Y1 does not intersect the first gate 820. The first gate 820 is shown in dashed line in FIG. 11A to indicate the location of the first gate 820 in the y direction and the z direction.

As shown in FIG. 11A, the supply rail 450 and the ground rail 455 are in-line vertically with the first source/drain 832 and the fourth source/drain 842 located between the supply rail 450 and the ground rail 455 in the z direction. In this example, the via 1014 is above a center of the first source/drain 832, and the via 1064 is below a center of the fourth source/drain 842.

FIG. 11B shows a cross-sectional view taken along cross-section line Y4-Y3 in FIG. 10A. As shown in FIG. 11B, the second source/drain 834 is coupled to the output signal path (i.e., the second portion 416-2 of the topside track 416 and the second portion 916-2 of the topside track 916 in this example) through the third topside contact 1042 and the vias 1044 and 1046. The third topside contact 1042 extends in the y direction from the top surface of the second source/drain 834 to an area directly below the second portion 416-2 of the topside track 416 to couple the second source/drain 834 to the second portion 416-2 of the topside track 416 through the via 1044. The third topside contact 1042 also extends in the y direction from the top surface of the second source/drain 834 to an area directly below the second portion 916-2 of the topside track 916 to couple the second source/drain 834 to the second portion 916-2 of the topside track 916 through the via 1046. Note that the cross-section line Y4-Y3 does not intersect the second gate 825. The second gate 825 is shown in dashed line in FIG. 11B to indicate the location of the second gate 825 in the y direction and the z direction.

FIG. 11C shows a cross-sectional view taken along cross-section line Y6-Y5 in FIG. 10A. As shown in FIG. 11C, the third source/drain 836 is coupled to the supply rail 450 (e.g., topside track 410) through the second topside contact 1032 and the via 1034. In this example, the via 1034 is above a center of the third source/drain 836.

Also, as shown in FIG. 11C, the sixth source/drain 846 is coupled to the first vertical connector 940 and the second vertical connector 960 through the second backside contact 1070, in which the second backside contact 1070 extends in the y direction from the bottom surface of the sixth source/drain 846 to the first vertical connector 940 and the second vertical connector 960.

In the example shown in FIG. 11C, the vias 934 and 954 are omitted. FIG. 11D shows another example in which the first vertical connector 940 is also coupled to the backside track 426 through the second via 934 and the second vertical connector 960 is also coupled to the backside track 926 through the second via 954.

It is to be appreciated that the CFET structure 810 is not limited to the exemplary routing shown FIGS. 10A, 10B, 11A, 11B, 11C, and 11D for implementing a NAND gate, and that other routing schemes are possible for implementing a NAND gate using the CFET structure 810.

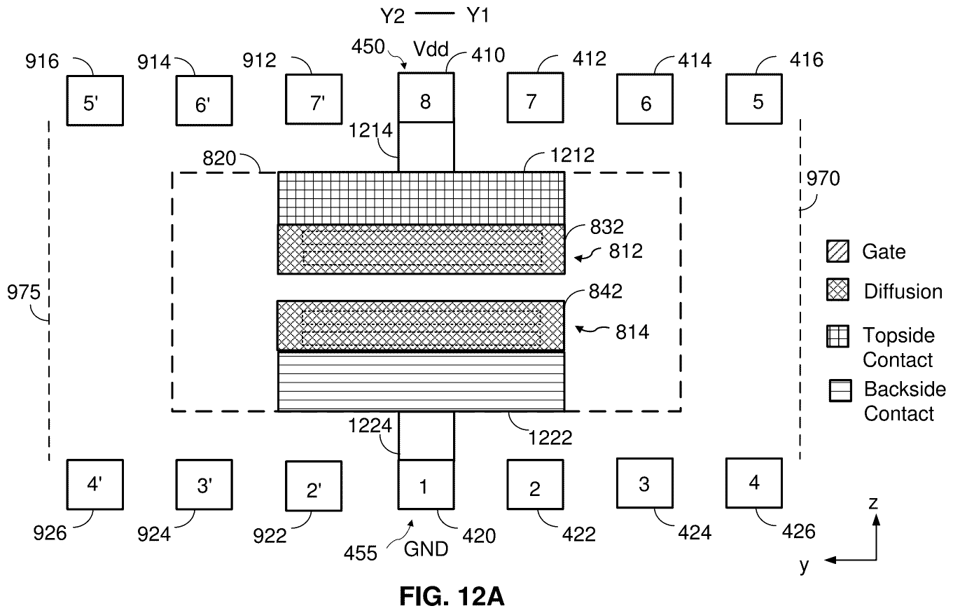

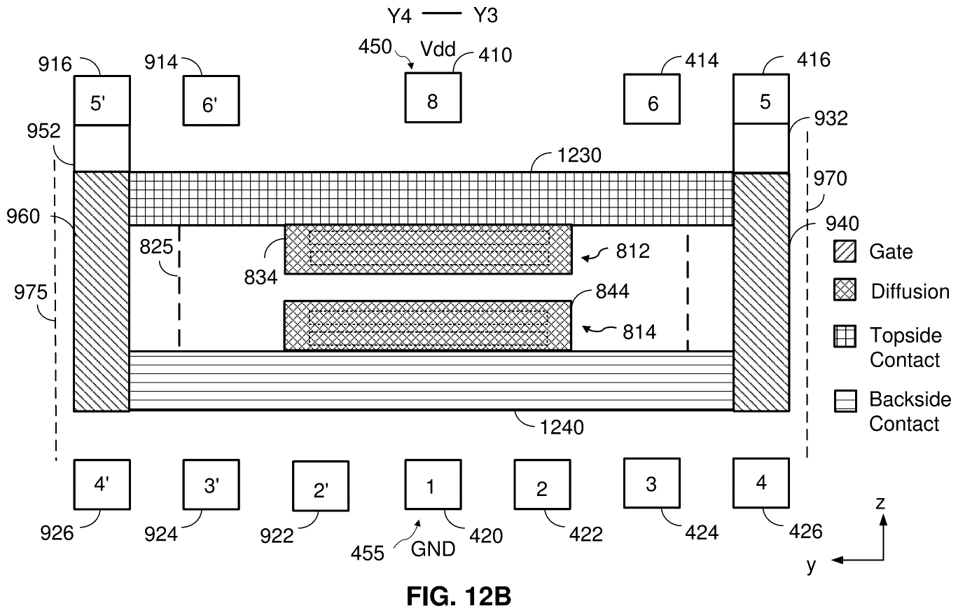

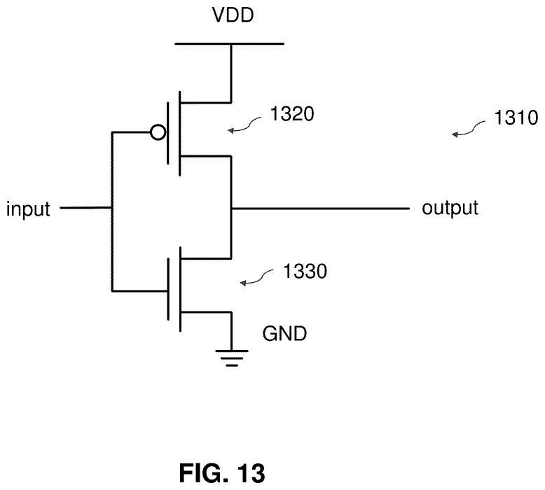

As discussed above, it is to be appreciated that the CFET structure 810 is not limited to a NAND gate, and that the CFET structure 810 may be used to implement other types of circuits. In this regard, FIGS. 12A and 12B shows cross-sectional views in which the CFET structure 810 is used to implement an inverter. A circuit schematic of the inverter is shown in FIG. 13.

FIG. 12A shows a cross-sectional view taken along cross-section line Y2-Y1. In this example, the first source/drain 832 is coupled to the supply rail 450 (e.g., topside track 410) through a first topside contact 1212 disposed on a top surface of the first source/drain 832 and the via 1214 disposed between the first topside contact 1212 and the supply rail 450. The fourth source/drain 842 is coupled to the ground rail 455 (e.g., the backside track 420) through a first backside contact 1222 disposed on a bottom surface of the fourth source/drain 842 and a via 1224 disposed between the first backside contact 1222 and the ground rail 455.

FIG. 12B shows a cross-sectional view taken along cross-section line Y4-Y3. In this example, a second topside contact 1230 is disposed on the top surface of the second source/drain 834. The second topside contact 1230 extends in the y direction to the first vertical connector 940 and the second vertical connector 960 to couple the second topside contact 1230 (and hence the second source/drain 834) to the first vertical connector 940 and the second vertical connector 960. The first vertical connector 940 is coupled to the track 416 through the via 932 and the second vertical connector 960 is coupled to the track 916 through the via 952. In this example, the tracks 416 and 916 may provide the output signal path for the inverter, in which the tracks 416 and 916 may be coupled (e.g., through metal layer M1).

In this example, a second backside contact 1240 is disposed on the bottom surface of the fifth source/drain 844. The second backside contact 1240 extends in the y direction to the first vertical connector 940 and the second vertical connector 960 to couple the second backside contact 1240 to the first vertical connector 940 and the second vertical connector 960. The vertical connectors 940 and 960 coupled the second backside contact 1240 (and hence the fifth source/drain 844) to the output signal path of the inverter.

FIG. 13 shows an example of an inverter 1310 implemented by the routing structure 905 and the CFET structure 810 shown in FIGS. 12A and 12B. The inverter 1310 includes a PFET 1320 and an NFET 1330, in which the source of the PFET 1320 is coupled to the supply rail (e.g., the topside track 410), the gates (e.g., the first gate 820) of the PFET 1320 and the NFET 1330 are coupled to the input of the inverter 1310 (labeled “input”), the drains of the PFET 1320 and the NFET 1330 are coupled to the output of the inverter 1310 (labeled “output”), and the source of the NFET 1330 is coupled to ground (e.g., the backside track 420).

In this example, the first source/drain 832, the first gate 820, and the second source/drain 834 provide the source, the gate, and the drain, respectively, of the PFET 1320. The fifth source/drain 844, the first gate 820, and the fourth source/drain 842 provide the drain, the gate, and the source, respectively, of the NFET 1330. In this example, the first gate 820 is a common gate shared by the PFET 1320 and the NFET 1330. The first gate 820 may be coupled to any one or more of the tracks 412, 416, 912, and 914 by respective vias to provide the input of the inverter 1310.

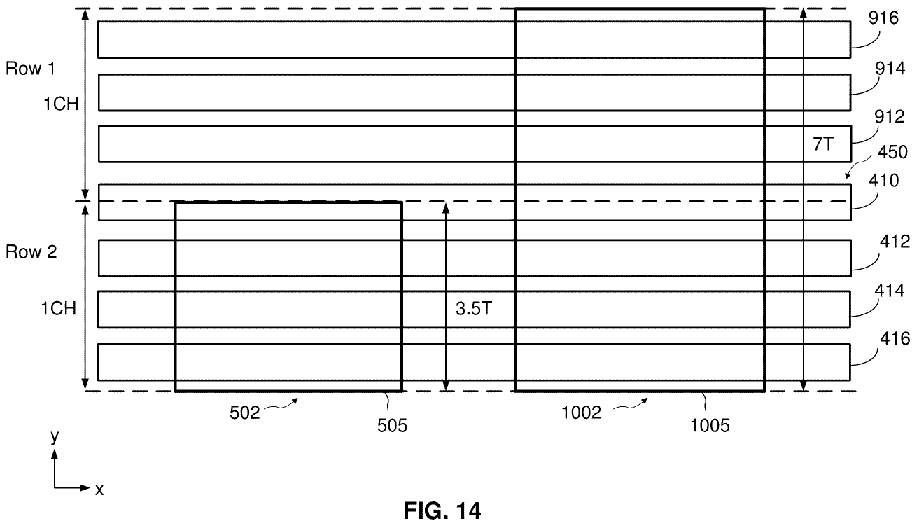

Multiple instances of the cell 502 and/or the cell 1002 may be arranged (i.e., laid out) in rows on the chip 100. In the regard, FIG. 14 shows a top view of an example of two rows including a first row (labeled “Row 1”) and a second row (labeled “Row 2”) where each row one has a height of 1CH in the y direction.

FIG. 14 also shows an example of the topside tracks 410, 412, 414, 416, 912, 914, and 916 extending in the x direction. In this example, the topside track 410 (e.g., the supply rail 450) lies on the boundary of the first row and the second row. This allows cells in the first row and the second row to share the supply rail 450, as discussed above with reference to FIG. 5C. In this example, the topside tracks 912, 914, and 916 are within the first row and the topside tracks 412, 414, and 416 are within the second row. In this example, the row height of 1CH is equal 3.5 T where T is the pitch of the topside tracks. However, it is to be appreciated that the present disclosure is not limited to this example. Although not shown in the top view of FIG. 14, it is to be appreciated that the backside tracks 420, 422, 424, 426, 922, 924, and 926 may be below the topside tracks 410, 412, 414, 416, 912, 914, and 916, respectively, in which the backside tracks 422, 424, and 426 are within the second row, the backside tracks 922, 924, and 926 are within the first row, and the backside track 420 (e.g., the ground rail 455) lies on the boundary of the first row and the second row.

FIG. 14 shows an example in which the cell 502 is placed in the second row and the cell 1002 with the wide diffusion regions (i.e., diffusion regions 812 and 814) is placed across the first row and the second row. Note that FIG. 14 only shows the boundary 505 of the cell 502 and the boundary 1005 of the cell 1002 for ease of illustration. Note that the boundaries 505 and 1005 are shown as think solid lines in FIG. 14.

In the example shown in FIG. 14, the supply rail 450 (e.g., the topside track 410) lies on an edge (e.g., the edge 480 shown in FIG. 4) of the cell 502 and extends over the cell 1002 (e.g., extends over the first diffusion region 812 shown in FIGS. 9A and 9B). In this example, both the cell 502 and the cell 1002 may use the supply rail 450 to receive the supply voltage Vdd. The ground rail 455 (not shown in FIG. 14) may lie on an edge (e.g., the edge 480 shown in FIG. 4) of the cell 502 and extend under the cell 1002 (e.g., extend under the second diffusion region 814 shown in FIGS. 9A and 9B). Also, this example, the cell 502 may use the topside tracks 412, 414, and 416 for signal routing and the cell 1002 may use the topside tracks 412, 414, 416, 912, 914, and 916 for signal routing. It is to be appreciated that one or more of the topside tracks 412, 414, and 416 may be cut between the cell 502 and the cell 1002 to separate the signal routing for the cell 502 and the cell 1002. It is also to be appreciated that one or more of the backside tracks 422, 424, and 426 (not shown in FIG. 14) may be cut between the cell 502 and the cell 1002.

In this example, the cell 502 has a cell height of 3.5 T and the cell 1002 has a cell height of 7 T. Thus, in this example, the cell 502 spans one row in the y direction and the cell 1002 spans across two rows (e.g., the first row and the second row) in the y direction.

In this example, the cell 502 may implement a NAND gate (e.g., the NAND gate 710), an inverter, or another type of circuit, and the cell 1002 may implement a NAND gate (e.g., the NAND gate 710), an inverter (e.g., the inverter 1310), or another type of circuit.

Implementation examples are described in the following numbered clauses:
1. A chip, comprising:
a first diffusion region extending in a first direction;
a second diffusion region extending in the first direction, wherein the first diffusion region and the second diffusion region are stacked in a second direction perpendicular to the first direction;
a first rail extending in the first direction, wherein the first diffusion region and the first rail are spaced apart in a third direction perpendicular to the first direction and the second direction;
a third diffusion region extending in the first direction, wherein the third diffusion region is wider than the first diffusion region in the third direction; and
a fourth diffusion region extending in the first direction, wherein the third diffusion region and the fourth diffusion region are stacked in the second direction.
2. The chip of clause 1, wherein the first rail extends over a center of the third diffusion region.
3. The chip of clause 2, wherein the first rail is a supply rail.
4. The chip of any one of clauses 1 to 3, further comprising a second rail extending in the first direction, wherein the second diffusion region and the second rail are spaced apart in the third direction, and the second rail extends under the fourth diffusion region.
5. The chip of clause 4, wherein the first rail extends over a center of the third diffusion region, and the second rail extends under a center of the fourth diffusion region.
6. The chip of clause 4 or 5, wherein the first rail is a supply rail and the second rail is a ground rail.
7. The chip of any one of clauses 1 to 6, wherein the first diffusion region comprises a first source/drain, the third diffusion region comprises a second source/drain, and the chip further comprises:
a first topside contact disposed on a top surface of the first source/drain, wherein the first topside contact extends in the third direction under the first rail;
a first via coupled between the first topside contact and the first rail;
a second topside contact disposed on a top surface of the second source/drain; and
a second via coupled between the second topside contact and the first rail.
8. The chip of clause 7, wherein the first via is spaced apart from the first source/drain in the third direction, and the second via is directly above the second source/drain.
9. The chip of clause 7 or 8, further comprising:
a first gate, wherein the first diffusion region comprises one or more first channels passing through the first gate and coupled to the first source/drain; and
a second gate, wherein the third diffusion region comprises one or more second channels passing through the second gate and coupled to the second source/drain.
10. The chip of clause 9, wherein the second gate is at least 1.5 wider than the first gate in the third direction.
11. The chip of clause 9 or 10, wherein each of the one or more second channels is at least 1.5 times wider than each of the one or more first channels in the third direction.
12. The chip of any one of clauses 9 to 11, wherein each of the one or more first channels comprises a respective nanosheet and each of the one or more second channels comprises a respective nanosheet.
13. A chip, comprising:
a first rail extending in a first direction;
a first track extending in the first direction;
a second track extending in the first direction, wherein the first rail is between the first track and the second track in a second direction perpendicular to the first direction;
a first diffusion region extending in the first direction, wherein the first rail extends over the first diffusion region;
a second diffusion region extending in the first direction, wherein the first diffusion region and the second diffusion region are stacked in a third direction perpendicular to the first direction and the second direction;
a first vertical connector extending in the third direction and coupled to the first track; and
a second vertical connector extending in the third direction and coupled to the second track.
14. The chip of clause 13, wherein the first vertical connector and the second vertical connector are located on opposite sides of the first diffusion region in the second direction.
15. The chip of clause 14, further comprising a backside contact disposed on a bottom surface of the second diffusion region, wherein the backside contact extends between the first vertical connector and the second vertical connector in the second direction, and the backside contact is coupled to the first vertical connector and the second vertical connector.
16. The chip of clause 15, further comprising a topside contact disposed on a top surface of the first diffusion region, wherein the topside contact extends in the second direction between the first vertical connector and the second vertical connector, and the topside contact is coupled to the first vertical connector and the second vertical connector.
17. The chip of clause 15, further comprising:
a topside contact disposed on a top surface of the first diffusion region, wherein the topside contact extends in the second direction under the first track; and
a first via coupled between the topside contact and the first track.
18. The chip of clause 17, wherein the topside contact extends in the second direction under the second track, and the chip further comprises a second via coupled between the topside contact and the second track.
19. The chip of any one of clauses 13 to 18, further comprising a second rail extending in the first direction under the second diffusion region.
20. The chip of clause 19, wherein the first rail is a supply rail and the second rail is a ground rail.
21. The chip of clause 19 or 20, further comprising:
a third track extending in the first direction;
a fourth track extending in the first direction, wherein the second rail is between the third track and the fourth track in the second direction.
22. The chip of clause 21, wherein the first rail, the first track, and the second track are formed in a topside metal layer, and the second rail, the third track, and the fourth track are formed in a backside metal layer.
23. The chip of clause 21 or 22, wherein the first vertical connector is coupled between the first track and the third track.
24. The chip of clause 23, wherein the second vertical connector is coupled between the second track and the fourth track.
25. The chip of clause 15, further comprising:
a topside contact disposed on a top surface of the first diffusion region; and
a via coupled between the topside contact and the first rail.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. As used herein, the term “approximately” means within 90 percent to 110 percent of the stated value.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element. For instance, the designations “first,” “second,” and “third” may be used to distinguish between the x, y, and z directions in any order. For example, the x direction, the z direction, and the y direction may be referred to as the first direction, the second direction, and the third direction, respectively, but is not limited to this example. In another example, the x direction, the y direction, and the z direction may be referred to as the first direction, the second direction, and the third direction, respectively.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
a first diffusion region extending in a first direction;
a second diffusion region extending in the first direction, wherein the first diffusion region and the second diffusion region are stacked in a second direction perpendicular to the first direction;
a first rail extending in the first direction, wherein the first diffusion region and the first rail are spaced apart in a third direction perpendicular to the first direction and the second direction;
a third diffusion region extending in the first direction, wherein the third diffusion region is wider than the first diffusion region in the third direction; and
a fourth diffusion region extending in the first direction, wherein the third diffusion region and the fourth diffusion region are stacked in the second direction.

2. The chip of claim 1, wherein the first rail extends over a center of the third diffusion region.

3. The chip of claim 2, wherein the first rail is a supply rail.

4. The chip of claim 1, further comprising a second rail extending in the first direction, wherein the second diffusion region and the second rail are spaced apart in the third direction, and the second rail extends under the fourth diffusion region.

5. The chip of claim 4, wherein the first rail extends over a center of the third diffusion region, and the second rail extends under a center of the fourth diffusion region.

6. The chip of claim 4, wherein the first rail is a supply rail and the second rail is a ground rail.

7. The chip of claim 1, wherein the first diffusion region comprises a first source/drain, the third diffusion region comprises a second source/drain, and the chip further comprises:
a first topside contact disposed on a top surface of the first source/drain, wherein the first topside contact extends in the third direction under the first rail;
a first via coupled between the first topside contact and the first rail;
a second topside contact disposed on a top surface of the second source/drain; and
a second via coupled between the second topside contact and the first rail.

8. The chip of claim 7, wherein the first via is spaced apart from the first source/drain in the third direction, and the second via is directly above the second source/drain.

9. The chip of claim 7, further comprising:
a first gate, wherein the first diffusion region comprises one or more first channels passing through the first gate and coupled to the first source/drain; and
a second gate, wherein the third diffusion region comprises one or more second channels passing through the second gate and coupled to the second source/drain.

10. The chip of claim 9, wherein the second gate is at least 1.5 wider than the first gate in the third direction.

11. The chip of claim 9, wherein each of the one or more second channels is at least 1.5 times wider than each of the one or more first channels in the third direction.

12. The chip of claim 9, wherein each of the one or more first channels comprises a respective nanosheet and each of the one or more second channels comprises a respective nanosheet.

13. A chip, comprising:
a first rail extending in a first direction;
a first track extending in the first direction;
a second track extending in the first direction, wherein the first rail is between the first track and the second track in a second direction perpendicular to the first direction;
a first diffusion region extending in the first direction, wherein the first rail extends over the first diffusion region;
a second diffusion region extending in the first direction, wherein the first diffusion region and the second diffusion region are stacked in a third direction perpendicular to the first direction and the second direction;
a first vertical connector extending in the third direction and coupled to the first track; and
a second vertical connector extending in the third direction and coupled to the second track.

14. The chip of claim 13, wherein the first vertical connector and the second vertical connector are located on opposite sides of the first diffusion region in the second direction.

15. The chip of claim 14, further comprising a backside contact disposed on a bottom surface of the second diffusion region, wherein the backside contact extends between the first vertical connector and the second vertical connector in the second direction, and the backside contact is coupled to the first vertical connector and the second vertical connector.

16. The chip of claim 15, further comprising a topside contact disposed on a top surface of the first diffusion region, wherein the topside contact extends in the second direction between the first vertical connector and the second vertical connector, and the topside contact is coupled to the first vertical connector and the second vertical connector.

17. The chip of claim 15, further comprising:
a topside contact disposed on a top surface of the first diffusion region, wherein the topside contact extends in the second direction under the first track; and
a first via coupled between the topside contact and the first track.

18. The chip of claim 17, wherein the topside contact extends in the second direction under the second track, and the chip further comprises a second via coupled between the topside contact and the second track.

19. The chip of claim 13, further comprising a second rail extending in the first direction under the second diffusion region.

20. The chip of claim 19, wherein the first rail is a supply rail and the second rail is a ground rail.
